(19) United States
(12) Patent Application Publication
(10) Pub. No.: US 2026/0047010 A1
(43) Pub. Date: Feb. 12, 2026

(54) WIRING SUBSTRATE

(71) Applicant: SHINKO ELECTRIC INDUSTRIES CO., LTD., Nagano-shi (JP)

(72) Inventor: Daisuke SAKURAI, Nagano-shi (JP)

(21) Appl. No.: 19/286,592

(22) Filed: Jul. 31, 2025

(30) Foreign Application Priority Data
Aug. 6, 2024 (JP) 2024-129813

(51) Int. Cl. H05K 1/18; H05K 3/00; H05K 3/24; H05K 3/30

(52) U.S. Cl. CPC H05K 1/188; H05K 3/0047; H05K 3/244; H05K 3/30; H05K 2201/09036; H05K 2201/10234; H05K 2201/10734; H05K 2201/10977; H05K 2203/072; H05K 2203/107

(57) ABSTRACT

A wiring substrate includes a first wiring layer, a first insulating layer, a second wiring layer electrically connected to the first wiring layer, “N” layers (“N” is a natural number of 1 or greater) of insulating layers including a second insulating layer, a cavity formed through the “N” layers of insulating layers and exposing an upper surface and a side surface of the second wiring layer, a surface-processed layer covering the upper surface and the side surface of the second wiring layer, an electronic component mounted on the surface-processed layer, a filling insulating layer filling the cavity and covering the electronic component, and a third wiring layer electrically connected to the electronic component. The side surface of the second wiring layer includes a first roughened surface, and the upper surface of the second wiring layer includes a second roughened surface having a greater surface roughness than the first roughened surface.

### CROSS-REFERENCE TO RELATED APPLICATIONS

This application is based upon and claims the benefit of priority from Japanese Patent Application No. 2024-129813, filed on Aug. 6, 2024, the entire contents of which are incorporated herein by reference.

### BACKGROUND

### 1. Field

The present disclosure relates to a wiring substrate and a method for manufacturing a wiring substrate.

### 2. Description of Related Art

JP2022-80677A describes a wiring substrate that incorporates an electronic component. This type of wiring substrate typically includes an electronic component mounted on conductive pads exposed at the bottom of a cavity formed through a plurality of insulating layers, and a filling insulating layer formed to fill the cavity and cover the electronic component. Such a wiring substrate may be manufactured as follows. First, conductive pads are formed, and a protective material is formed to cover the conductive pads. Then, multiple insulating layers are stacked to cover the conductive pads and the protective material. Subsequently, a given region is removed from the insulating layers to form a cavity that exposes the protective material, and the protective material is removed to expose the conductive pads. After mounting an electronic component on the conductive pads, a filling insulating layer is formed to fill the cavity and cover the electronic component.

### SUMMARY

In the above-described wiring substrate, there is a demand for improvement in the connection reliability between the electronic component and the conductive pads exposed at the bottom of the cavity.

In one general aspect, a wiring substrate includes a first wiring layer, a first insulating layer, a second wiring layer, “N” layers (“N” is a natural number greater than or equal to 1) of insulating layers, a cavity, a surface-processed layer, an electronic component, a filling insulating layer, and a third wiring layer. The first insulating layer covers the first wiring layer. The second wiring layer is stacked on an upper surface of the first insulating layer and is electrically connected to the first wiring layer. The “N” layers of insulating layers include a second insulating layer stacked on the upper surface of the first insulating layer. The cavity is formed through the “N” layers of insulating layers and exposes an upper surface and a side surface of the second wiring layer. The surface-processed layer covers the upper surface and the side surface of the second wiring layer exposed in the cavity. The electronic component is arranged in the cavity and is mounted on the surface-processed layer. The filling insulating layer fills the cavity and covers the electronic component. The third wiring layer is stacked on an upper surface of the filling insulating layer and is electrically connected to the electronic component. The side surface of the second wiring layer includes a first roughened surface. The upper surface of the second wiring layer includes a second roughened surface having a greater surface roughness than the first roughened surface.

Other features and aspects will be apparent from the following detailed description, the drawings, and the claims.

### BRIEF DESCRIPTION OF THE DRAWINGS

FIG. 1 is a schematic cross-sectional view of a wiring substrate in accordance with a first embodiment.

FIG. 2 is a schematic cross-sectional view enlarging part of the wiring substrate illustrated in FIG. 1.

FIGS. 3, 4, 5, 6, 7, 8, 9, 10, 11, 12, 13, 14, 15, and 16 are schematic cross-sectional views illustrating a method for manufacturing the wiring substrate illustrated in FIG. 1.

FIG. 17 is a schematic cross-sectional view enlarging part of a wiring substrate in accordance with a second embodiment.

FIG. 18 is a schematic cross-sectional view illustrating a method for manufacturing the wiring substrate illustrated in FIG. 17.

FIGS. 19, 20, 21, 22, 23, 24, 25, 26, and 27 are schematic cross-sectional views illustrating the method for manufacturing the wiring substrate illustrated in FIG. 17.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Embodiments will now be described with reference to the drawings. The accompanying drawings may not be drawn to scale, and the relative size, proportions, and depiction of elements may be exaggerated for clarity, illustration, or convenience. To facilitate understanding, hatching lines may not be illustrated or may be replaced by shadings in cross-sectional views. In the description of the present disclosure, a numerical range of “X1 to X2,” which is specified by the lower limit value X1 and the upper limit value X2, refers to a range that is greater than or equal to X1 and less than or equal to X2, unless otherwise specified.

### First Embodiment

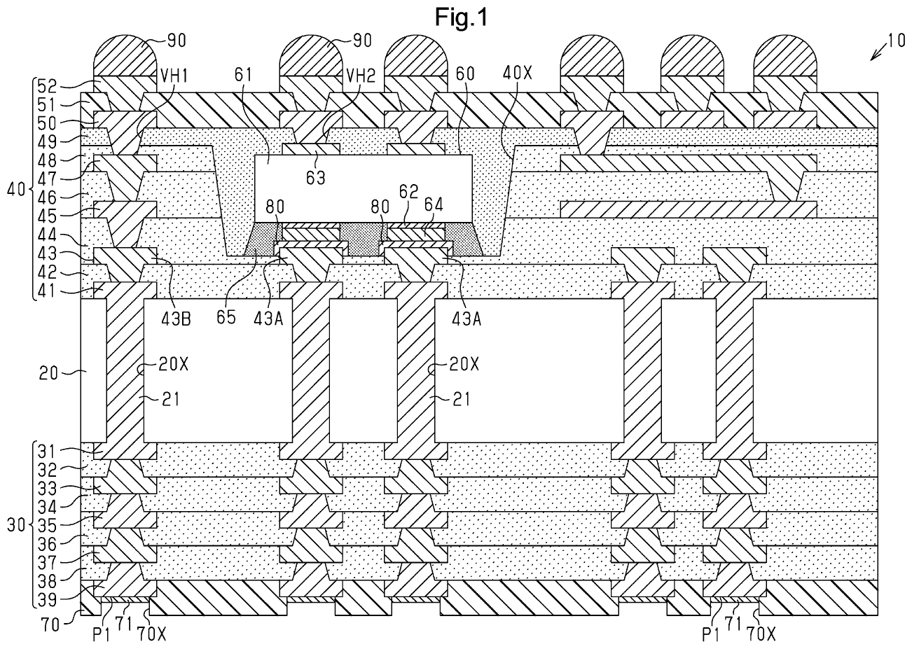

A first embodiment will now be described with reference to FIGS. 1 to 16. In this specification, “plan view” refers to a view of a subject taken in a vertical direction (e.g., top-bottom direction in FIG. 1), and “planar shape” refers to a shape of a subject as viewed in the vertical direction. Furthermore, in the present specification, “top-bottom direction” and “left-right direction” correspond to directions when the drawings are oriented to an appropriate position allowing reference numerals of the elements to be read correctly.

### Overall Structure of Wiring Substrate 10

As illustrated in FIG. 1, a wiring substrate 10 includes a core substrate 20, a wiring structure 30, a wiring structure 40, a cavity 40X formed in the wiring structure 40, and one or more (in the present embodiment, one) electronic components 60 arranged in the cavity 40X. The wiring substrate 10 includes an underfill resin 65, a solder resist layer 70, and external connection terminals 90. The wiring substrate 10 incorporates the electronic component 60. The wiring structure 30 and the solder resist layer 70 are arranged on one side of the core substrate 20, and the wiring structure 40 and the external connection terminals 90 are arranged on the other side of the core substrate 20.

In the present embodiment, to facilitate understanding, the side of the wiring substrate 10 on which the solder resist layer 70 is arranged in FIG. 1 will be referred to as “the lower side” or “one side”, and the side of the wiring substrate 10 on which the external connection terminals 90 are arranged will be referred to as “the upper side” or “the other side”. Also, in the present embodiment, to facilitate understanding, a surface of each component located at a side corresponding to the solder resist layer 70 will be referred to as “one surface” or “the lower surface”, and a surface of each component located at another side corresponding to the external connection terminals 90 will be referred to as “the other surface” or “the upper surface”. The wiring substrate 10 may be used in a state flipped upside down or may be arranged at any angle.

The core substrate 20 may be, for example, a glass epoxy substrate in which a glass cloth is impregnated with a thermosetting insulating resin, such as an epoxy-based resin or the like. The core substrate 20 may be, for example, a substrate in which a woven cloth or non-woven cloth of glass fibers, carbon fibers, aramid fibers, or the like, is impregnated with a thermosetting insulating resin, such as an epoxy-based resin or the like. The glass cloth or the like is not illustrated in the drawings.

The core substrate 20 includes a plurality of through holes 20X extending through the core substrate 20 in a thickness-wise direction. The through holes 20X may have any planar shape and any planar size. For example, the through holes 20X may each have a circular planar shape having a diameter of approximately 50 μm to 200 μm.

A through-electrode 21 extending through the core substrate 20 in the thickness-wise direction is formed in each through hole 20X. For example, the through hole 20X is filled with the through-electrode 21. The material of the through-electrode 21 may be, for example, copper (Cu) or a copper alloy.

### Wiring Structure 30

The wiring structure 30 is stacked on the lower surface of the core substrate 20. The wiring structure 30 of the present embodiment includes a structure in which a wiring layer 31, an insulating layer 32, a wiring layer 33, an insulating layer 34, a wiring layer 35, an insulating layer 36, a wiring layer 37, an insulating layer 38, and a wiring layer 39 are sequentially stacked on the lower surface of the core substrate 20.

The material of the wiring layers 31, 33, 35, 37, and 39 may be, for example, copper or a copper alloy. The wiring layers 31, 33, 35, 37, and 39 may each have a thickness of, for example, approximately 8 μm to 35 μm. The wiring layers 31, 33, 35, 37, and 39 may each have a line/space (L/S) of, for example, approximately 10 μm/10 μm to 50 μm/50 μm. The “line” in “line/space” indicates the width of wiring, and the “space” indicates the distance (wiring interval) between adjacent wiring parts. For example, when the line/space is 10 μm/10 μm to 50 μm/50 μm, the wiring width is 10 μm or greater and 50 μm or less, and the wiring interval is 10 μm or greater and 50 μm or less. The wiring width does not have to be equal to the wiring interval.

The insulating layers 32, 34, 36, and 38 each include a non-photosensitive resin as a main component. The insulating layers 32, 34, 36, and 38 may each include, for example, a thermosetting non-photosensitive resin, such as an epoxy-based resin, an imide-based resin, a phenol-based resin, a cyanate-based resin, or the like, as a main component. The insulating layers 32, 34, 36, and 38 may each have a thickness of, for example, approximately 35 μm to 100 μm.

The wiring layer 31 is formed on the lower surface of the core substrate 20. The wiring layer 31 is electrically connected to the through-electrodes 21. The insulating layer 32 is formed on the lower surface of the core substrate 20 and covers the wiring layer 31. The wiring layer 33 is formed on the lower surface of the insulating layer 32. The wiring layer 33 is electrically connected to the wiring layer 31 by via wiring extending through the insulating layer 32 in the thickness-wise direction.

The insulating layer 34 is formed on the lower surface of the insulating layer 32 and covers the wiring layer 33. The wiring layer 35 is formed on the lower surface of the insulating layer 34. The wiring layer 35 is electrically connected to the wiring layer 33 by via wiring extending through the insulating layer 34 in the thickness-wise direction. The insulating layer 36 is formed on the lower surface of the insulating layer 34 and covers the wiring layer 35. The wiring layer 37 is formed on the lower surface of the insulating layer 36. The wiring layer 37 is electrically connected to the wiring layer 35 by via wiring extending through the insulating layer 36 in the thickness-wise direction. The insulating layer 38 is formed on the lower surface of the insulating layer 36 and covers the wiring layer 37. The wiring layer 39 is formed on the lower surface of the insulating layer 38. The wiring layer 39 is electrically connected to the wiring layer 37 by via wiring extending through the insulating layer 38 in the thickness-wise direction.

### Structure of Solder Resist Layer 70

The solder resist layer 70 is the outermost insulating layer (here, the lowermost insulating layer) of the wiring substrate 10. The solder resist layer 70 is formed on the lower surface of the wiring structure 30 and covers the lowermost wiring layer 39. In the example illustrated in FIG. 1, the solder resist layer 70 is formed on the lower surface of the lowermost insulating layer 38 of the wiring structure 30. The solder resist layer 70 is an insulating layer including a photosensitive resin as a main component. The material of the solder resist layer 70 may be, for example, a photosensitive insulating resin including a phenol-based resin, a polyimide-based resin, or the like, as a main component. The solder resist layer 70 may include, for example, a filler, such as silica, alumina, or the like.

The solder resist layer 70 includes openings 70X that expose parts of the lower surface of the lowermost wiring layer 39 as external connection pads P1. The external connection pads P1 are connected to external connection terminals when mounting the wiring substrate 10 on a mounting substrate, such as a motherboard or the like.

A surface-processed layer 71 may be formed on the wiring layer 39 exposed in the openings 70X. Examples of the surface-processed layer 71 include a Au layer, a Ni layer/Au layer (metal layer in which the Ni layer serves as bottom layer, and the Au layer is formed on the Ni layer), and a Ni layer/Pd layer/Au layer (metal layer in which the Ni layer serves as bottom layer, and the Pd layer and the Au layer are sequentially formed on the Ni layer). The Au layer is a metal layer of Au or a Au alloy. The Ni layer is a metal layer of Ni or a Ni alloy. The Pd layer is a metal layer of Pd or a Pd alloy. For example, the Au layer, the Ni layer, and the Pd layer may each be a metal layer formed by electroless plating (electroless plating metal layer). Alternatively, the surface-processed layer 71 may be an organic solderability preservative (OSP) film formed by performing an oxidation-resisting process, such as an OSP process, on the surface of the external connection pads P1. The OSP film may be, for example, an organic coating of an azole compound, an imidazole compound, or the like. The wiring layer 39 exposed in the openings 70X (or surface-processed layer 71, if surface-processed layer 71 is formed on wiring layer 39) may be used as external connection terminals.

The external connection pads Pl and the openings 70X may have any planar shape and any planar size. For example, the external connection pads P1 and the openings 70X may each have, for example, a circular planar shape having a diameter of approximately 200 μm to 300 μm.

### Wiring Structure 40

The wiring structure 40 is stacked on the upper surface of the core substrate 20. The wiring structure 40 of the present embodiment includes a structure in which a wiring layer 41, an insulating layer 42, a wiring layer 43, an insulating layer 44, a wiring layer 45, an insulating layer 46, a wiring layer 47, an insulating layer 48, an insulating layer 49, a wiring layer 50, an insulating layer 51, and a wiring layer 52 are sequentially stacked on the upper surface of the core substrate 20.

The material of the wiring layers 41, 43, 45, 47, 50, and 52 may be, for example, copper or a copper alloy. The wiring layers 41, 43, 45, 47, 50, and 52 may each have a thickness of, for example, approximately 10 μm to 30 μm. The wiring layers 41, 43, 45, 47, 50, and 52 may each have a line/space of, for example, approximately 10 μm/10 μm to 50 μm/50 μm.

The insulating layers 42, 44, 46, 48, 49, and 51 each include, for example, a non-photosensitive resin as a main component. The insulating layers 42, 44, 46, 48, 49, and 51 may each include, for example, a thermosetting non-photosensitive resin, such as an epoxy-based resin, an imide-based resin, a phenol-based resin, a cyanate-based resin, or the like, as a main component. The insulating layer 51 may include a photosensitive resin as a main component, in the same manner as the solder resist layer 70. In this case, the material of the insulating layer 51 may be, for example, a photosensitive insulating resin including a phenol-based resin, a polyimide-based resin, or the like, as a main component.

The wiring layer 41 is formed on the upper surface of the core substrate 20. The wiring layer 41 is electrically connected to the wiring layer 31 by the through-electrodes 21. The insulating layer 42 is formed on the upper surface of the core substrate 20 and covers the wiring layer 41. The distance from the upper surface of the wiring layer 41 to the upper surface of the insulating layer 42 may be, for example, approximately 25 μm to 40 μm.

The wiring layer 43 is stacked on the upper surface of the insulating layer 42. The wiring layer 43 is electrically connected to the wiring layer 41 by via wiring extending through the insulating layer 42 in the thickness-wise direction. The wiring layer 43 includes a wiring layer 43A and a wiring layer 43B. The wiring layer 43A overlaps the cavity 40X in plan view. The wiring layer 43B does not overlap the cavity 40X in plan view.

The insulating layer 44 is formed on the upper surface of the insulating layer 42 and covers the wiring layer 43. The distance from the upper surface of the wiring layer 43 to the upper surface of the insulating layer 44 may be, for example, approximately 30 μm to 60 μm.

The wiring layer 45 is stacked on the upper surface of the insulating layer 44. The wiring layer 45 is electrically connected to the wiring layer 43 by via wiring extending through the insulating layer 44 in the thickness-wise direction. The wiring layer 45 does not overlap the cavity 40X in plan view.

The insulating layer 46 is formed on the upper surface of the insulating layer 44 and covers the wiring layer 45. The distance from the upper surface of the wiring layer 45 to the upper surface of the insulating layer 46 may be, for example, approximately 30 μm to 60 μm.

The wiring layer 47 is stacked on the upper surface of the insulating layer 46. The wiring layer 47 is electrically connected to the wiring layer 45 by via wiring extending through the insulating layer 46 in the thickness-wise direction. The wiring layer 47 does not overlap the cavity 40X in plan view.

The insulating layer 48 is formed on the upper surface of the insulating layer 46 and covers the wiring layer 47. The distance from the upper surface of the wiring layer 47 to the upper surface of the insulating layer 48 may be, for example, approximately 25 μm to 40 μm.

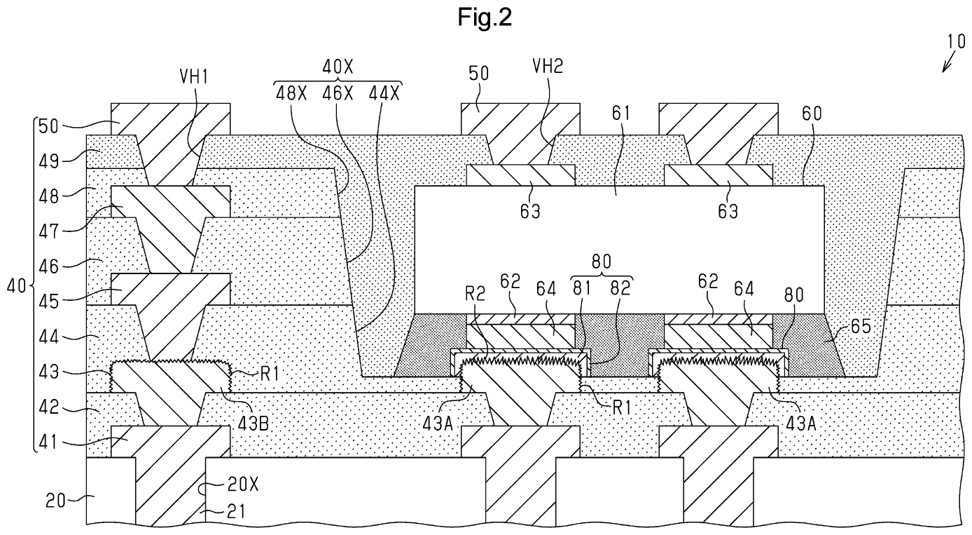

The cavity 40X is formed through the insulating layers 44, 46, and 48. The cavity 40X is recessed from the upper surface of the insulating layer 48 to an intermediate part of the insulating layer 44 in the thickness-wise direction. The cavity 40X exposes the upper surface and the side surface of the wiring layer 43A. In the example illustrated in FIG. 2, the cavity 40X exposes the entire upper surface of the wiring layer 43A and part of the side surface of the wiring layer 43. The cavity 40X is formed in correspondence with the electronic component 60 to be incorporated. That is, the cavity 40X is formed at a position where the electronic component 60 is to be mounted.

As illustrated in FIG. 2, the cavity 40X of the present embodiment includes a through hole 48X extending through the insulating layer 48 in the thickness-wise direction, a through hole 46X extending through the insulating layer 46 in the thickness-wise direction, and a recess 44X formed in the upper surface of the insulating layer 44. The through hole 48X, the through hole 46X, and the recess 44X are continuous with one another. For example, the wall surface of the through hole 48X, the wall surface of the through hole 46X, and the wall surface of the recess 44X are continuous with one another. The through hole 48X, the through hole 46X, and the recess 44X are, for example, coaxial. That is, the through hole 48X, the through hole 46X, and the recess 44X share the same center axis. The bottom surface of the recess 44X, or the bottom surface of the cavity 40X, is located at an intermediate part of the insulating layer 44 in the thickness-wise direction. The bottom surface of the cavity 40X is located downward from the upper surface of the wiring layer 43A. In other words, the upper part of the wiring layer 43A projects upward from the bottom surface of the cavity 40X. The distance from the upper surface of the insulating layer 42 to the bottom surface of the cavity 40X may be, for example, approximately 3 μm to 8 μm.

The cavity 40X is, for example, tapered such that its opening width decreases from the upper side (upper surface of insulating layer 48) toward the lower side (core substrate 20) in FIG. 2. That is, the cavity 40X includes the bottom surface having a lower opening and an upper open end having an upper opening that is wider than the lower opening. The space surrounded by the wall surface and the bottom surface of the cavity 40X, or the inside of the cavity 40X, serves as an accommodation space for the electronic component 60. In this manner, in the wiring substrate 10 of the present example, the three insulating layers 44, 46, and 48 stacked on the lowermost insulating layer 42 of the wiring structure 40 serve as cavity formation insulating layers. FIG. 2 does not illustrate the insulating layer 51, the wiring layer 52, and the external connection terminals 90 to simplify illustration.

The electronic component 60 is mounted on the wiring layer 43A exposed in the cavity 40X. The wiring layer 43A acts as electronic component mounting pads for electrical connection to the electronic component 60.

The side surface of the wiring layer 43A includes a first roughened surface R1. The upper surface of the wiring layer 43A includes a second roughened surface R2 having a greater surface roughness than the first roughened surface R1. Thus, the upper surface of the wiring layer 43A is roughened to have a greater surface roughness than the side surface of the wiring layer 43A. For example, the side surface of the wiring layer 43A includes the first roughened surface R1 at a portion covered by the insulating layer 44 and a portion exposed in the cavity 40X. In other words, a portion of the side surface of the wiring layer 43A covered by the insulating layer 44 has substantially the same roughness as a portion of the side surface of the wiring layer 43A exposed in the cavity 40X. The first roughened surface R1 may have a surface roughness Ra of, for example, approximately 80 nm to 130 nm. The second roughened surface R2 may have a surface roughness Ra of, for example, approximately 250 nm to 450 nm. The surface roughness Ra is a type of numerical indicator representing a surface roughness, and is also referred to as the arithmetic mean roughness. The surface roughness Ra is calculated as the arithmetic mean of absolute values of height deviations within a measurement region, relative to a surface that serves as a mean line.

The upper surface and the side surface of the wiring layer 43B each include the first roughened surface R1. Therefore, the upper surface and the side surface of the wiring layer 43B have substantially the same roughness. The upper surface and the side surface of the wiring layer 43B are roughened to have a smaller surface roughness than the upper surface of the wiring layer 43A, or the second roughened surface R2.

A surface-processed layer 80 is formed on the surfaces of the wiring layer 43A exposed in the cavity 40X. The surface-processed layer 80 covers the entire upper surface of the wiring layer 43A, and the entire side surface of the wiring layer 43A exposed in the cavity 40X. The surface-processed layer 80 may be an OSP film or a metal layer, such as a Au layer, a Ni layer/Au layer, a Ni layer/Pd layer/Au layer, or the like.

The surface-processed layer 80 of the present embodiment includes a stack of a first metal layer 81 and a second metal layer 82. The first metal layer 81 covers the entire surface of the wiring layer 43A exposed in the cavity 40X. Preferably, the material of the first metal layer 81 is, for example, a conductive material having a higher adhesion to the wiring layer 43B than the metal of the second metal layer 82. The first metal layer 81 of the present embodiment is a Ni layer. The second metal layer 82 covers the entire upper surface and the entire side surface of the first metal layer 81. The second metal layer 82 of the present embodiment is a Au layer. The first metal layer 81 may have a thickness of, for example, approximately 1 μm to 9 μm. The second metal layer 82 may have a thickness of, for example, approximately 10 nm to 90 nm.

The upper surfaces and side surfaces of the wiring layers 41, 45, 47, 50, and 52 are roughened to include a roughened surface similar to the first roughened surface R1, except for the wiring layer 43. However, the upper surfaces and side surfaces of the wiring layers 41, 45, 47, 50, and 52 are illustrated as smooth surfaces in the drawings to simplify illustration.

### Structure of Electronic Component 60

The electronic component 60 includes a main body 61, a first electrode 62 arranged on the lower surface of the main body 61, and a second electrode 63 arranged on the upper surface of the main body 61. The electronic component 60 of the present embodiment includes a plurality of first electrodes 62 arranged on the lower surface of the main body 61 and a plurality of second electrodes 63 arranged on the upper surface of the main body 61. The electronic component 60 is, for example, flip-chip mounted on the wiring layer 43A exposed in the cavity 40X. The first electrodes 62 of the electronic component 60 are electrically connected to the surface-processed layer 80, which is formed on the surfaces of the wiring layer 43A exposed in the cavity 40X. The first electrodes 62 are electrically connected to the surface-processed layer 80 by bonding members 64. In this manner, the electronic component 60 is electrically connected to the wiring layer 43A by the first electrodes 62, the bonding members 64, and the surface-processed layer 80.

The electronic component 60 may be, for example, a semiconductor element, a crystal oscillator, or a chip component. Examples of the chip component may include a chip capacitor, a chip resistor, and a chip inductor. The electronic component 60 incorporated in the wiring substrate 10 does not have to be of a single type. The wiring substrate 10 may incorporate different types of electronic components 60.

The main body 61 is, for example, box-shaped. The main body 61 may have a thickness of, for example, approximately 50 μm to 100 μm. The main body 61 is formed from, for example, silicon (Si) or silicon carbide (SiC).

The material of the first electrodes 62 and the second electrodes 63 may be, for example, a metal, such as aluminum (Al) or copper (Cu), or an alloy including at least one selected from these metals.

The first electrodes 62 respectively face different parts of the wiring layer 43A. In an example, the first electrodes 62 project downward from the lower surface of the main body 61. The first electrodes 62 may have a thickness of, for example, approximately 2 μm to 20 μm. The first electrodes 62 may be embedded in the main body 61.

In an example, the second electrodes 63 project upward from the upper surface of the main body 61. The upper surface of the second electrodes 63 are, for example, coplanar with the upper surface of the insulating layer 48. The second electrodes 63 may have a thickness of, for example, approximately 2 μm to 20 μm. The second electrodes 63 may be embedded in the main body 61.

### Structure of Bonding Member 64

The bonding members 64 are, for example, bonded to the first electrodes 62 and the surface-processed layer 80. The bonding members 64 electrically connect the first electrodes 62 and the surface-processed layer 80. The bonding members 64 may be, for example, a solder layer. The material of the solder layer may be, for example, lead (Pb)-free solder of tin (Sn)-silver (Ag), Sn—Cu, or Sn—Ag—Cu. The bonding members 64 may have a thickness of, for example, approximately 5 μm to 30 μm.

### Structure of Underfill Resin 65

The underfill resin 65 is formed between the electronic component 60 and the bottom surface of the cavity 40X. The underfill resin 65 fills the gap between the lower surface of the main body 61 of the electronic component 60 and the bottom surface of the cavity 40X. The underfill resin 65 encapsulates the first electrodes 62, the bonding members 64, and the surface-processed layer 80. The material of the underfill resin 65 may be, for example, an insulating resin, such as an epoxy-based resin or the like.

### Insulating Layer 49

The insulating layer 49 is a filling insulating layer that fills the cavity 40X. The insulating layer 49 covers the upper surface of the insulating layer 48, fills the cavity 40X, and covers the electronic component 60. The insulating layer 49 covers the underfill resin 65. The insulating layer 49 covers, for example, the entire side surface of the underfill resin 65. The insulating layer 49 covers, for example, the entire bottom surface of the cavity 40X exposed from the underfill resin 65. The insulating layer 49 covers, for example, the entire wall surface of the cavity 40X exposed from the underfill resin 65. The insulating layer 49 covers, for example, the entire electronic component 60 exposed from the underfill resin 65. The insulating layer 49 covers, for example, the side surface and the upper surface of the main body 61 exposed from the underfill resin 65. The insulating layer 49 covers, for example, the side surface and the upper surface of the second electrodes 63.

The insulating layer 49 covers, for example, the entire upper surface of the insulating layer 48. The insulating layers 48 and 49 include through holes VH1 at given locations. The through holes VH1 extend through the insulating layers 48 and 49 in the thickness-wise direction and expose parts of the upper surface of the wiring layer 47. The insulating layer 49 includes through holes VH2 at given locations. The through holes VH2 extend through the insulating layer 49 in the thickness-wise direction and expose parts of the upper surface of the second electrodes 63. The through holes VH1 and VH2 are, for example, each tapered such that its diameter (opening width) decreases from the upper side (upper surface of insulating layer 49) toward the lower side (core substrate 20) in FIG. 2. The through holes VH1 and VH2 each have the shape of an inverted truncated cone such that the lower open end has a smaller diameter than the upper open end. The distance from the upper surface of the insulating layer 48 to the upper surface of the insulating layer 49 may be, for example, approximately 15 μm to 45 μm.

The wiring layer 50 is formed on the upper surface of the insulating layer 49. The wiring layer 50 includes, for example, a wiring pattern electrically connected to the wiring layer 47 by via wiring filling the through holes VH1. The wiring layer 50 includes, for example, a wiring pattern electrically connected to the second electrodes 63 by via wiring filling the through holes VH2. The wiring layer 50 is, for example, formed integrally with the via wiring filling the through holes VH1 or the through holes VH2. The wiring layer 50 may be laid out on the upper surface of the insulating layer 49 in a planar direction (direction orthogonal to stacking direction of wiring substrate 10 in cross-sectional view). Further, the wiring layer 50 laid out as described above may electrically connect part of the wiring layer 50 connected to the wiring layer 47 and part of the wiring layer 50 connected to the second electrodes 63.

As illustrated in FIG. 1, the insulating layer 51 is formed on the upper surface of the insulating layer 49 and covers the wiring layer 50. The insulating layer 51 is the outermost insulating layer (here, the uppermost insulating layer) of the wiring substrate 10. The distance from the upper surface of the wiring layer 50 to the upper surface of the insulating layer 51 may be, for example, approximately 25 μm to 40 μm.

The wiring layer 52 is stacked on the upper surface of the insulating layer 51. The wiring layer 52 is electrically connected to the wiring layer 50 by via wiring extending through the insulating layer 51 in the thickness-wise direction. The wiring layer 52 is, for example, the outermost wiring layer (here, the uppermost wiring layer) of the wiring substrate 10. The wiring layer 52 acts as, for example, electronic component mounting pads for electrical connection to an electronic component (not illustrated), such as a semiconductor element or the like.

A surface-processed layer may be formed on a surface (upper and side surfaces or upper surface only) of the wiring layer 52. The surface-processed layer may be an OSP film or a metal layer, such as a Au layer, a Ni layer/Au layer, a Ni layer/Pd layer/Au layer, or the like.

The external connection terminals 90 are, for example, arranged on the upper surface of the wiring layer 52. The external connection terminals 90 may be, for example, solder balls. The material of the solder balls may be, for example, Pb-free solder of Sn—Ag, Sn—Cu, or Sn—Ag—Cu.

### Method for Manufacturing Wiring Substrate 10

A method for manufacturing the wiring substrate 10 will now be described. In particular, a method for manufacturing the wiring substrate 10 illustrated in FIG. 2 will be described. To facilitate understanding, portions that will consequently become elements of the wiring substrate 10 are given the same reference characters as the final elements.

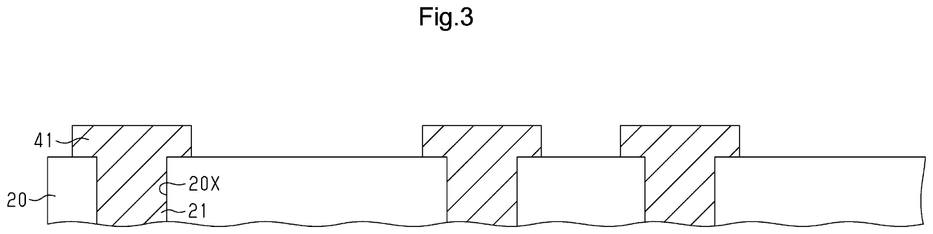

First, in the step illustrated in FIG. 3, a structural body is formed including the core substrate 20, the through-electrodes 21, and the wiring layer 41 formed on the upper surface of the core substrate 20. This structural body may be manufactured by a known process. Thus, the process will not be described in detail.

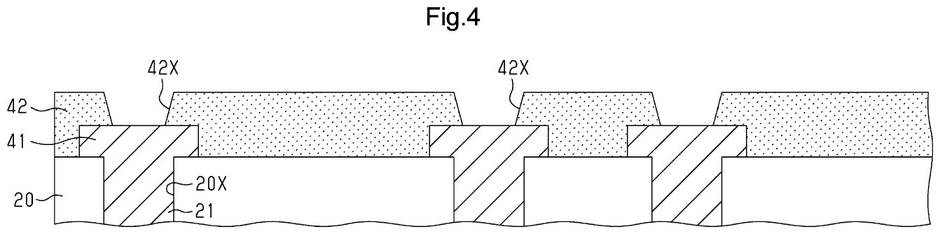

In the subsequent step illustrated in FIG. 4, the insulating layer 42 is formed on the upper surface of the core substrate 20 to cover the wiring layer 41. In an example in which a resin film is used as the insulating layer 42, the upper surface of the core substrate 20 is laminated with the resin film. Then, the resin film is heated at a curing temperature or higher (e.g., approximately 130° C. to 200° C.) while being pressed so that the resin film may be cured to form the insulating layer 42. The resin film may be, for example, a film of a thermosetting resin including an epoxy-based resin as a main component. In another example in which a liquid or a paste of insulating resin is used as the insulating layer 42, the liquid or paste of insulating resin is applied to the upper surface of the core substrate 20 by spin coating or the like. Then, the applied insulating resin is heated at a curing temperature or higher so that the insulating resin may be cured to form the insulating layer 42. The liquid or paste of insulating resin may be, for example, a thermosetting resin including an epoxy-based resin as a main component.

Subsequently, through holes 42X are formed at given locations of the insulating layer 42 to expose parts of the upper surface of the wiring layer 41. The through holes 42X may be formed by, for example, laser drilling using CO₂ laser, UV-YAG laser, or the like.

In a case in which the through holes 42X are formed by laser drilling, a desmear process is performed to remove resin smears from the surface of the wiring layer 41 exposed at the bottom of the through holes 42X. The desmear process in this step may be, for example, a wet desmear process using a potassium permanganate solution or the like.

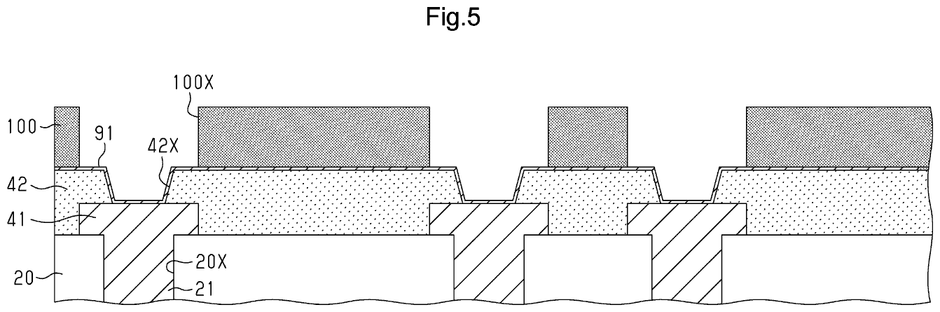

In the subsequent step illustrated in FIG. 5, a seed layer 91 is formed to cover the entire upper surface of the insulating layer 42 and the entire wall surfaces of the through holes 42X. The seed layer 91 may be formed by, for example, sputtering or electroless plating. In an example in which the seed layer 91 is formed by sputtering, titanium (Ti) is first sputtered and deposited on the upper surface of the insulating layer 42 and the wall surfaces of the through holes 42X so that a Ti layer covers the upper surface of the insulating layer 42 and the wall surfaces of the through holes 42X. Then, copper is sputtered and deposited on the Ti layer to form a Cu layer. This forms the seed layer 91 having a double-layer structure (Ti layer/Cu layer). In another example in which the seed layer 91 is formed by electroless plating, electroless copper plating may be performed to form the seed layer 91 having a Cu layer (single-layer structure).

Subsequently, a resist layer 100 including an opening pattern 100X is formed on the seed layer 91 at a given location. The opening pattern 100X exposes parts of the seed layer 91 that correspond to regions in which the wiring layer 43 is formed (refer to FIG. 2). The material of the resist layer 100 may be, for example, a material resistant to electrolytic plating performed in the subsequent step. For example, the material of the resist layer 100 may be a photosensitive dry film resist or a liquid photoresist (e.g., dry film resist or liquid resist of novolac-based resin or acrylic-based resin). In an example in which a photosensitive dry film resist is used, the upper surface of the seed layer 91 is laminated with a dry film by thermocompression bonding, and then the dry film is patterned by photolithography to form the resist layer 100 including the opening pattern 100X. In another example in which a liquid photoresist is used, the resist layer 100 may also be formed by a similar process.

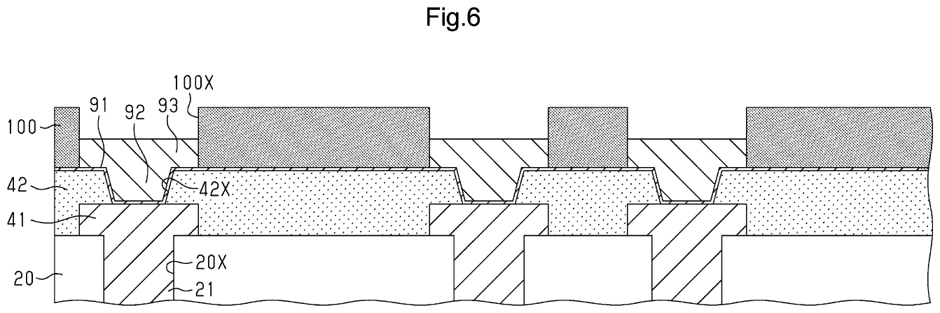

In the subsequent step illustrated in FIG. 6, electrolytic plating is performed on the seed layer 91 using the resist layer 100 as a plating mask and the seed layer 91 as a plating power feeding layer. That is, electrolytic plating (here, electrolytic Cu plating) is performed on the upper surface of the seed layer 91 exposed in the opening pattern 100X of the resist layer 100. This step forms a metal layer 92 and a metal layer 93. The metal layer 92 fills the through holes 42X surrounded by the seed layer 91. The metal layer 93 is formed in the opening pattern 100X.

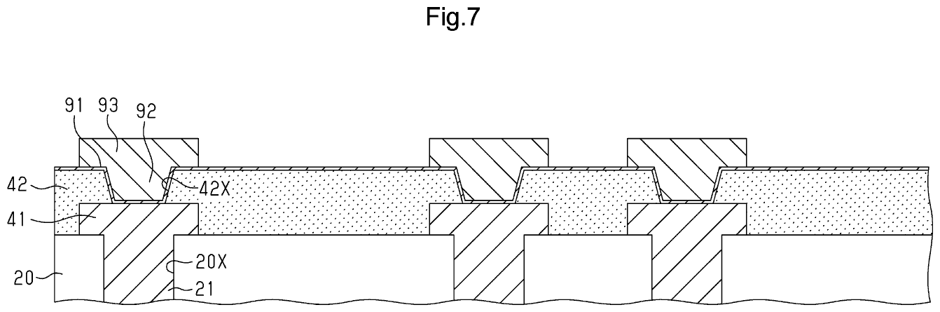

In the subsequent step illustrated in FIG. 7, the resist layer 100 illustrated in FIG. 6 is removed using an alkaline stripping solution (e.g., organic amine-based stripping solution, caustic soda, acetone, ethanol, or the like).

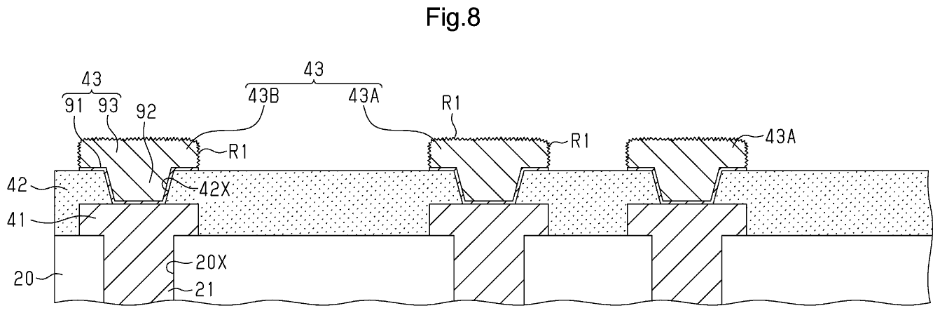

In the subsequent step illustrated in FIG. 8, unnecessary parts of the seed layer 91 are removed by etching using the metal layer 93 as an etching mask. This step forms via wiring and the wiring layer 43. The via wiring includes the seed layer 91 and the metal layer 92, which are formed inside the through holes 42X. The via wiring fills the through holes 42X. The wiring layer 43 includes the seed layer 91 and the metal layer 93. The wiring layer 43 is formed on the upper surface of the insulating layer 42. In this case, the wiring layer 43 includes the wiring layer 43A that overlaps the cavity 40X in plan view (refer to FIG. 2), and the wiring layer 43B that does not overlap the cavity 40X in plan view. The cavity 40X is formed in a later step. In FIGS. 1 and 2, the seed layer 91 and the metal layer 93 are not illustrated to simplify illustration.

Subsequently, a roughening process is performed on the wiring layers 43A and 43B. This roughening process forms the first roughened surface R1 on the entire upper surface and the entire side surface of the wiring layer 43A and the entire upper surface and the entire side surface of the wiring layer 43B. In particular, this step forms the first roughened surface R1 having a smaller surface roughness than the second roughened surface R2 illustrated in FIG. 2 on the upper surface of the wiring layer 43A. The roughening process may be performed by, for example, blackening, etching, blasting, or the like.

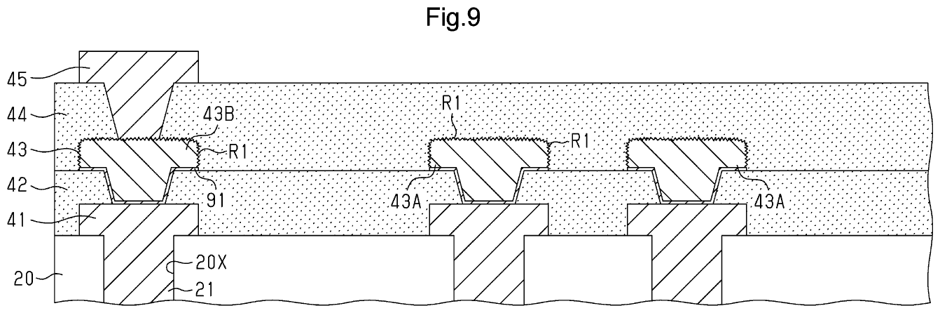

In the subsequent step illustrated in FIG. 9, steps similar to those illustrated in FIGS. 4 to 8 are performed to stack the insulating layer 44 and the wiring layer 45 on the upper surface of the insulating layer 42.

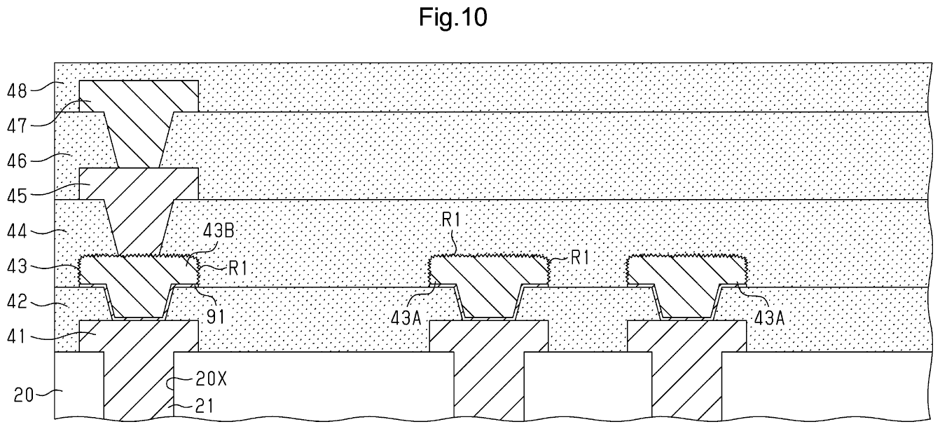

In the subsequent step illustrated in FIG. 10, steps similar to those illustrated in FIGS. 4 to 8 are performed to stack the insulating layer 46 and the wiring layer 47 on the upper surface of the insulating layer 44. Further, the insulating layer 48 is stacked on the upper surface of the insulating layer 46 to cover the wiring layer 47. In this case, the insulating layer 48 covers the entire upper surface and the entire side surface of the wiring layer 47.

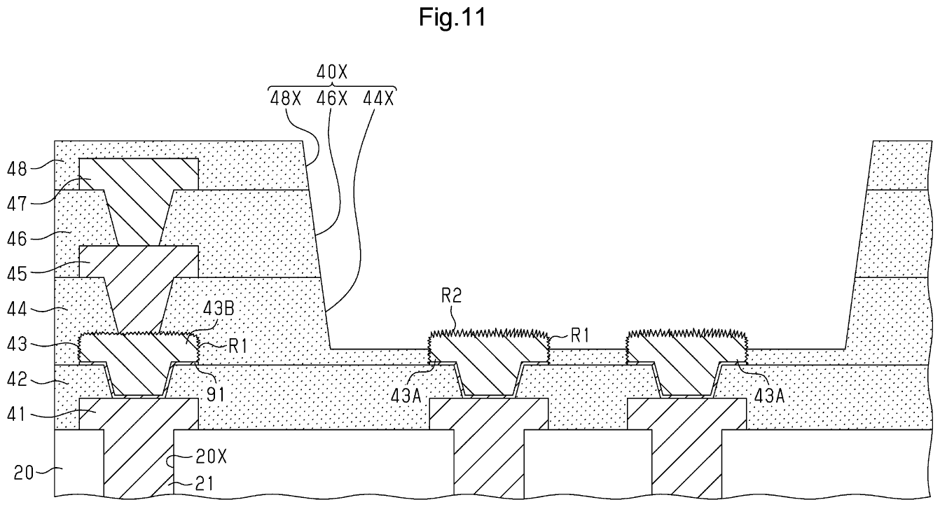

In the subsequent step illustrated in FIG. 11, the cavity 40X is formed to expose the upper surface and the side surface of the wiring layer 43A. The cavity 40X is recessed from the upper surface of the insulating layer 48 toward the insulating layer 42 In the present example, the through hole 48X is formed to extend through the insulating layer 48 in the thickness-wise direction, the through hole 46X is formed to be continuous with the through hole 48X and extends through the insulating layer 46, and the recess 44X is formed to be continuous with the through hole 46X and recessed from the upper surface of the insulating layer 44. That is, the cavity 40X extends through the insulating layers 48 and 46 to an intermediate part of the insulating layer 44 in the thickness-wise direction. The cavity 40X exposes part of the side surface of the wiring layer 43A, or an upper part of the side surface of the wiring layer 43A in FIG. 11. The bottom surface of the cavity 40X is located upward from the upper surface of the seed layer 91. In particular, the cavity 40X is formed so that the thickness of the insulating layer 44 between the bottom surface of the cavity 40X and the upper surface of the insulating layer 42 is greater than the thickness of the seed layer 91. In other words, the depth of the cavity 40X is set so that the remainder of the insulating layer 44 is thicker than the seed layer 91. In this manner, even if the unnecessary parts of the seed layer 91 are not completely removed by the step illustrated in FIG. 8, the insulating layer 44 covers the remainder of the seed layer 91. As a result, the remainder of the unnecessary parts of the seed layer 91 will not be exposed in the cavity 40X.

The cavity 40X may be formed by, for example, laser drilling using CO₂ laser, UV-YAG laser, or the like. In the laser drilling, the upper surface of the wiring layer 43 A is irradiated with a laser beam. This emission of the laser beam further roughens the upper surface of the wiring layer 43A. That is, the laser drilling increases the roughness of the upper surface of the wiring layer 43A. As a result, the upper surface of the wiring layer 43A roughened by laser drilling in the present step includes the second roughened surface R2 having a greater surface roughness than the first roughened surface R1. Accordingly, the upper surface of the wiring layer 43A and the side surface of the wiring layer 43A have different surface roughness.

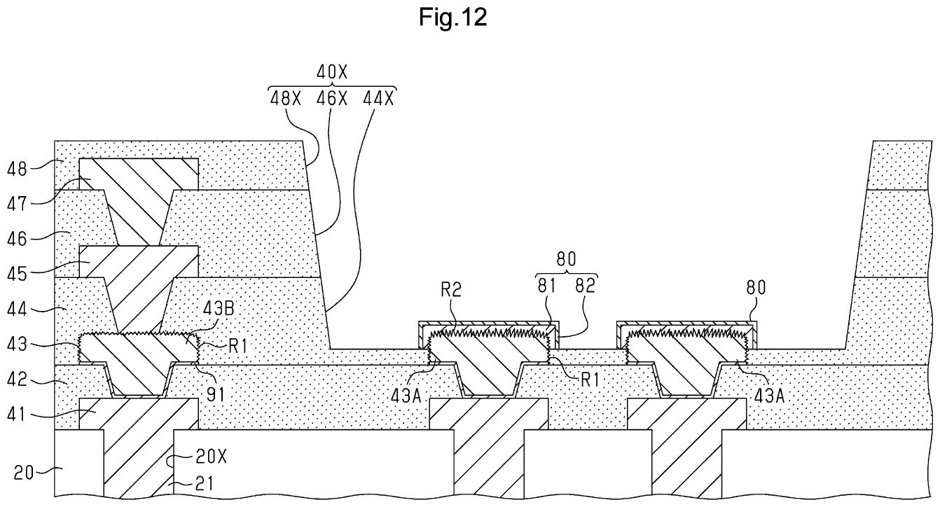

In the subsequent step illustrated in FIG. 12, the surface-processed layer 80 is formed on the surfaces of the wiring layer 43A exposed in the cavity 40X. The surface-processed layer 80 covers the entire upper surface and the entire side surface of the wiring layer 43A exposed in the cavity 40X. The surface-processed layer 80 may be formed by, for example, electroless plating. In an example, electroless plating (here, electroless Ni plating) is performed to form the first metal layer 81 (Ni layer) that covers the entire surface of the wiring layer 43A exposed in the cavity 40X. Then, electroless plating (here, electroless Au plating) is performed to form the second metal layer 82 (Au layer) that covers the entire surface of the first metal layer 81. In the present step, if the unnecessary parts of the seed layer 91 are not completely removed by the step illustrated in FIG. 8, a plating film may deposit on the surface of the remainder of the seed layer 91 exposed in the cavity 40X. Such unintended deposition of the plating film may cause short-circuiting between adjacent parts of the wiring layer 43A. In this respect, in the present embodiment, the depth of the cavity 40X is set so that the insulating layer 44 is thicker than the seed layer 91. Accordingly, the insulating layer 44 covers any remainder of the unnecessary parts of the seed layer 91. This avoids unintended deposition of a plating film, thereby minimizing occurrence of short-circuiting caused by such a plating film.

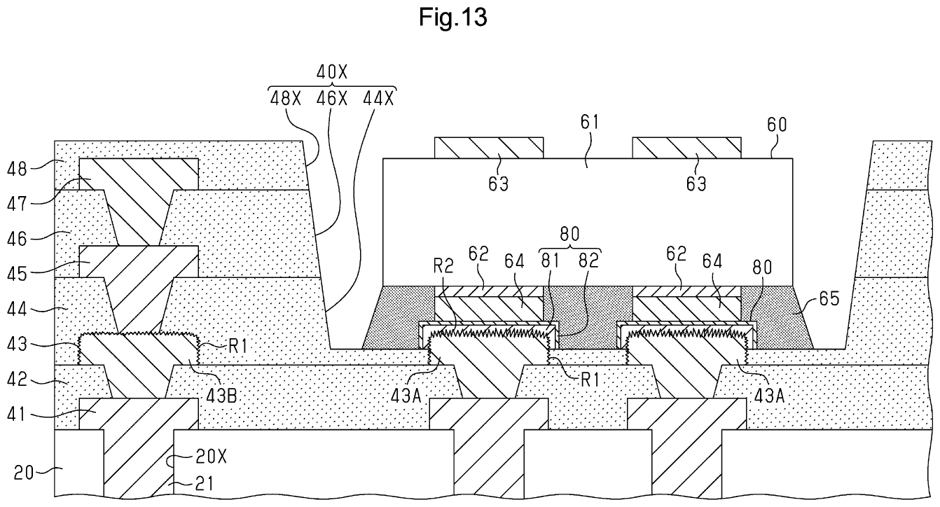

In FIGS. 13 to 16, the seed layer 91 and the metal layers 92 and 93 are not illustrated, and the wiring layer 43 is illustrated as a single layer.

In the subsequent step illustrated in FIG. 13, the electronic component 60 is prepared. The electronic component 60 includes the main body 61, the first electrodes 62, and the second electrodes 63. Then, the electronic component 60 is mounted on the surface-processed layer 80 in the cavity 40X. In the present example, the first electrodes 62 of the electronic component 60 are bonded by the bonding members 64 to the surface-processed layer 80, which is formed on the surfaces of the wiring layer 43A. In an example in which the bonding members 64 are a solder layer, flux (not illustrated) is applied to the surface-processed layer 80, and then the first electrodes 62 are positioned relative to the surface-processed layer 80 in a state in which the bonding members 64 are arranged between the first electrodes 62 and the surface-processed layer 80. Then, reflow soldering is performed at a temperature of approximately 230° C. to 260° C. This melts the solder layer serving as the bonding members 64, so that the bonding members 64 electrically connect the surface-processed layer 80 and the first electrodes 62. Subsequently, the underfill resin 65 is added to fill the gap between the bottom surface of the cavity 40X and the lower surface of the main body 61 of the electronic component 60, and then the underfill resin 65 is cured.

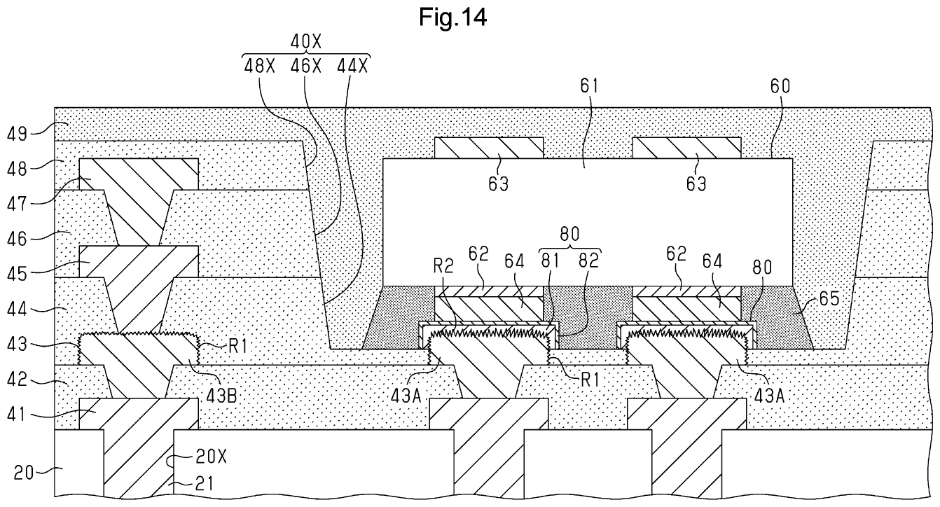

In the subsequent step illustrated in FIG. 14, a step similar to that illustrated in FIG. 4 is performed to form the insulating layer 49 that covers the upper surface of the insulating layer 48 and fills the cavity 40X. The insulating layer 49 covers the entire side surface of the underfill resin 65 and the entire surface of the electronic component 60 exposed from the underfill resin 65.

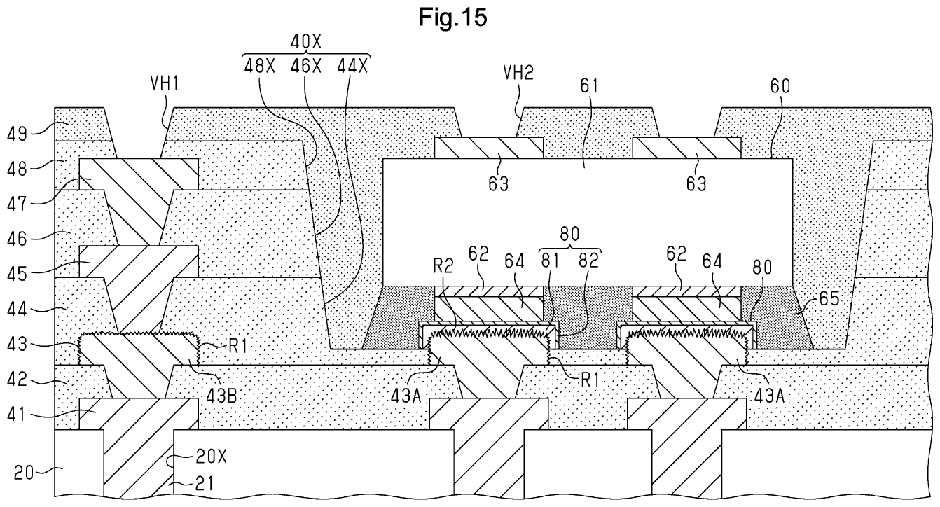

In the subsequent step illustrated in FIG. 15, a step similar to that illustrated in FIG. 4 is performed to form the through holes VH1 at given locations of the insulating layers 48 and 49. The through holes VH1 extend through the insulating layers 48 and 49 in the thickness-wise direction and expose parts of the upper surface of the wiring layer 47. Also, the through holes VH2 are formed at given locations of the insulating layer 49. The through holes VH2 extend through the insulating layer 49 in the thickness-wise direction and expose parts of the upper surface of the second electrode 63.

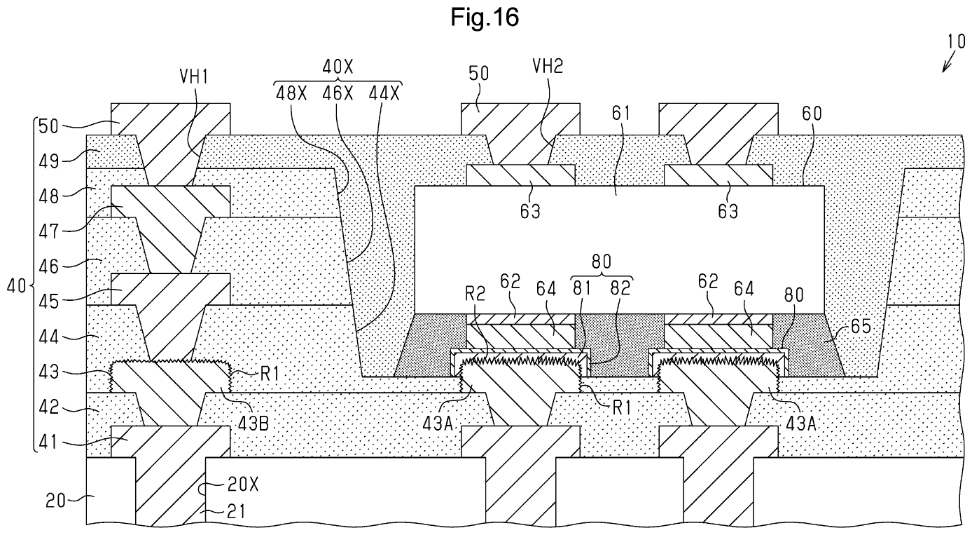

In the subsequent step illustrated in FIG. 16, steps similar to those illustrated in FIGS. 5 to 8 are performed to form via wiring filling the through holes VH1, and stack the wiring layer 50 on the upper surface of the insulating layer 49. In this manner, the wiring layer 50 is electrically connected to the wiring layer 47 by the via wiring. Also, via wiring is formed to fill the through holes VH2, and the wiring layer 50 is stacked on the upper surface of the insulating layer 49. In this manner, the wiring layer 50 is electrically connected to the second electrodes 63 by the via wiring.

The structural body illustrated in FIG. 2 may be manufactured as described above. Thereafter, the insulating layer 51, the wiring layer 52, and the like illustrated in FIG. 1 are formed to manufacture the wiring substrate 10 of the present embodiment.

### Operation and Advantages of First Embodiment

The first embodiment has the following advantages.
(1-1) The wiring substrate 10 includes the wiring layer 41, the insulating layer 42 covering the wiring layer 41, and the wiring layer 43A stacked on the upper surface of the insulating layer 42 and electrically connected to the wiring layer 41. The wiring substrate 10 includes “N” layers (here, “N” is three) of insulating layers and the cavity 40X. The “N” layers of insulating layers, namely, the insulating layers 44, 46, and 48, include the insulating layer 44 stacked on the upper surface of the insulating layer 42. The cavity 40X is formed through the “N” insulating layers 44, 46, and 48 to expose the upper surface and the side surface of the wiring layer 43A. The wiring substrate 10 includes the surface-processed layer 80 and the electronic component 60. The surface-processed layer 80 covers the upper surface and the side surface of the wiring layer 43A exposed in the cavity 40X. The electronic component 60 is arranged in the cavity 40X and is mounted on the surface-processed layer 80. The wiring substrate 10 includes the insulating layer 49 and the wiring layer 50. The insulating layer 49 fills the cavity 40X and covers the electronic component 60. The wiring layer 50 is stacked on the upper surface of the insulating layer 49 and is electrically connected to the electronic component 60. The side surface of the wiring layer 43A includes the first roughened surface R1. The upper surface of the wiring layer 43A includes the second roughened surface R2 having a greater surface roughness than the first roughened surface R1.

With this structure, the upper surface and the side surface of the wiring layer 43A are roughened. Then, the surface-processed layer 80 is formed to cover the roughened side surface and the roughened upper surface of the wiring layer 43A. This increases the area of contact between the surface-processed layer 80 and the side surface and the upper surface of the wiring layer 43A, as compared to a structure in which the side surface and the upper surface of the wiring layer 43A are smooth. As a result, the adhesion between the wiring layer 43A and the surface-processed layer 80 is improved. This restricts delamination of the surface-processed layer 80 from the wiring layer 43A, and improves the connection reliability between the wiring layer 43A and the surface-processed layer 80. Consequently, the connection reliability between the wiring layer 43A and the electronic component 60 through the surface-processed layer 80 is improved.
(1-2) The upper surface of the wiring layer 43A includes the second roughened surface R2 having a greater surface roughness than the side surface of the wiring layer 43A. This further increases the area of contact between the upper surface of the wiring layer 43A and the surface-processed layer 80, thereby further improving the adhesion between the upper surface of the wiring layer 43A and the surface-processed layer 80. As a result, delamination of the surface-processed layer 80 from the wiring layer 43A is further restricted.
(1-3) In a typical method for manufacturing a wiring substrate, conductive pads are first formed, and a protective material is formed to cover the conductive pads. Then, multiple insulating layers are stacked to cover the conductive pads and the protective material. Subsequently, a given region is removed from the insulating layers to form a cavity that exposes the protective material, and the protective material is removed to expose the conductive pads. In such a manufacturing method, the conductive pads are covered by the protective material when the cavity is formed, such that the surfaces of the conductive pads will not be roughened. Accordingly, the surfaces of the conductive pads are smooth. As a result, when a surface-processed layer is formed on the surfaces of such conductive pads, the adhesion between the conductive pads and the surface-processed layer may be relatively poor. This may delaminate the surface-processed layer from the conductive pads.

In this respect, the method for manufacturing the wiring substrate 10 of the present embodiment does not form a protective material that covers the wiring layer 43A. Further, after the wiring layer 43A is roughened, the “N” layers of insulating layers, namely, the insulating layers 44, 46, and 48, are formed. The “N” insulating layers 44, 46, and 48 include the insulating layer 44 that covers the wiring layer 43A. Then, the cavity 40X is formed through the insulating layers 44, 46, and 48 by laser drilling to expose the upper surface and the side surface of the wiring layer 43A. In such a manufacturing method, a roughening process is performed before the insulating layer 44 is formed, so that the upper surface and the side surface of the wiring layer 43A may each include the first roughened surface R1. Furthermore, laser drilling is performed, so that the upper surface of the wiring layer 43A may include the second roughened surface R2 having a greater surface roughness than the first roughened surface R1. This increases the area of contact between the surface-processed layer 80 and the side surface and the upper surface of the wiring layer 43A, as compared to a structure in which the side surface and the upper surface of the wiring layer 43A are smooth. As a result, the adhesion between the wiring layer 43A and the surface-processed layer 80 is improved.
(1-4) The wiring layer 43B is stacked on the upper surface of the insulating layer 42, and does not overlap the cavity 40X in plan view. The side surface and the upper surface of the wiring layer 43B each include the first roughened surface R1. With this structure, the upper surface of the wiring layer 43A is roughened to have a greater surface roughness than the upper surface and the side surface of the wiring layer 43B, which is coplanar with the wiring layer 43A. This further increases the area of contact between the upper surface of the wiring layer 43A and the surface-processed layer 80, thereby further improving the adhesion between the upper surface of the wiring layer 43A and the surface-processed layer 80. As a result, delamination of the surface-processed layer 80 from the wiring layer 43A is further restricted.
(1-5) The cavity 40X is recessed from the upper surface of the uppermost insulating layer 48 of the “N” insulating layers 44, 46, and 48 to an intermediate part of the insulating layer 44 in the thickness-wise direction. The cavity 40X exposes part of the side surface of the wiring layer 43A. The bottom surface of the cavity 40X is located upward from the upper surface of the seed layer 91.

With this structure, even if unnecessary parts of the seed layer 91 are not completely removed by the step illustrated in FIG. 8, the insulating layer 44 covers the remainder of the seed layer 91. As a result, the remainder of the unnecessary parts of the seed layer 91 will not be exposed in the cavity 40X. This avoids unintended deposition of a plating film on the remainder of the unnecessary parts of the seed layer 91 when forming the surface-processed layer 80, thereby minimizing occurrence of short-circuiting caused by such a plating film.

### Second Embodiment

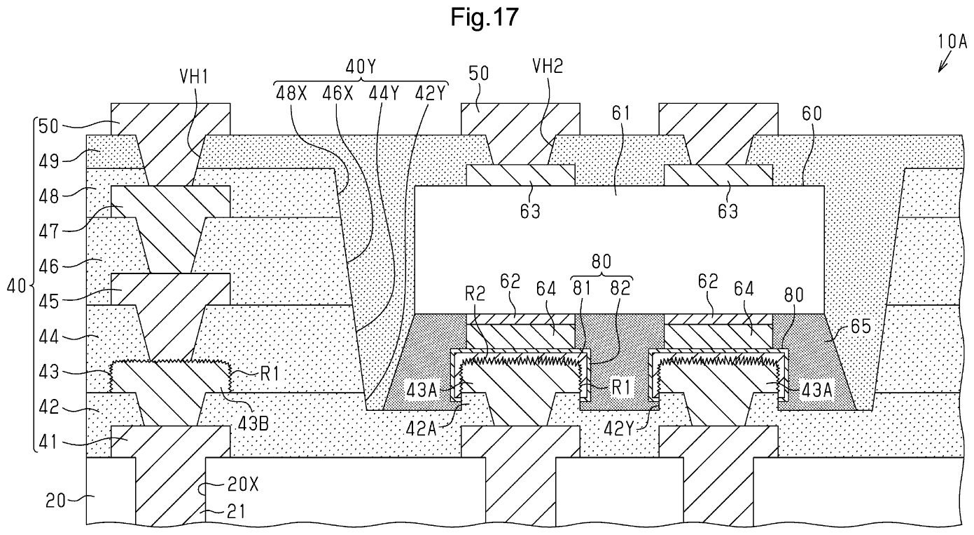

A second embodiment will now be described with reference to FIGS. 17 to 27. A wiring substrate 10A of the present embodiment differs from the wiring substrate 10 of the first embodiment in the structures of a cavity 40Y and the surface-processed layer 80 in the wiring structure 40. Hereafter, differences from the first embodiment will be mainly described. The same reference characters are given to those components that are the same as the corresponding components illustrated in FIGS. 1 to 16. Such components will not be described in detail.

### Wiring Structure 40

As illustrated in FIG. 17, the wiring structure 40 includes the cavity 40Y. The cavity 40Y of the present embodiment is formed through the insulating layers 42, 44, 46, and 48. The cavity 40Y is recessed from the upper surface of the insulating layer 48 to an intermediate part of the insulating layer 42 in the thickness-wise direction. The cavity 40Y exposes the entire upper surface of the wiring layer 43A and the entire side surface of the wiring layer 43A. The cavity 40Y is formed in correspondence with the electronic component 60 to be incorporated.

The cavity 40Y includes the through hole 48X extending through the insulating layer 48 in the thickness-wise direction, the through hole 46X extending through the insulating layer 46 in the thickness-wise direction, a through hole 44Y extending through the insulating layer 44 in the thickness-wise direction, and a recess 42Y formed in the upper surface of the insulating layer 42. The through hole 48X, the through hole 46X, the through hole 44Y, and the recess 42Y are continuous with one another. For example, the wall surface of the through hole 48X, the wall surface of the through hole 46X, the wall surface of the through hole 44Y, and the wall surface of the recess 42Y are continuous with one another. The through hole 48X, the through hole 46X, the through hole 44Y, and the recess 42Y are, for example, coaxial. That is, the through hole 48X, the through hole 46X, the through hole 44Y, and the recess 42Y share the same center axis.

The bottom surface of the recess 42Y, or the bottom surface of the cavity 40Y, is located at an intermediate part of the insulating layer 42 in the thickness-wise direction. The bottom surface of the cavity 40Y is located downward from the lower surface of the wiring layer 43A. The bottom surface of the cavity 40Y is located upward from the upper surface of the wiring layer 41. The depth of the recess 42Y, that is, the distance from the upper surface of the insulating layer 42 to the bottom surface of the recess 42Y, may be, for example, approximately 3 μm to 8 μm.

In an example, in plan view, the recess 42Y overlaps the through hole 44Y and does not overlap the wiring layer 43A. That is, the recess 42Y is not formed in a portion of the upper surface of the insulating layer 42 where the insulating layer 42 overlaps the wiring layer 43A in plan view. In other words, the insulating layer 42 includes a projection 42A projecting upward from the bottom surface of the recess 42Y at a portion where the insulating layer 42 overlaps the wiring layer 43A in plan view.

The cavity 40Y is, for example, tapered as a whole such that its opening width decreases from the upper side (upper surface of insulating layer 48) toward the lower side (core substrate 20) in FIG. 17. That is, the cavity 40Y includes the bottom surface having a lower opening and an upper open end having an upper opening that is wider than the lower opening. For example, the side surface of the projection 42A extends perpendicularly to the upper surface of the insulating layer 42.

The space surrounded by the wall surface and the bottom surface of the cavity 40Y, or the inside of the cavity 40Y, serves as an accommodation space for the electronic component 60. In this manner, in the wiring substrate 10A of the present example, the four insulating layers 42, 44, 46, and 48 stacked on the core substrate 20 serve as cavity formation insulating layers. To simplify illustration, FIG. 17 does not include the insulating layer 51, the wiring layer 52, and the external connection terminals 90, which are illustrated in FIG. 1.

The side surface of the wiring layer 43A includes the first roughened surface R1. The upper surface of the wiring layer 43A includes the second roughened surface R2 having a greater surface roughness than the first roughened surface R1. The entire side surface and entire upper surface of the wiring layer 43A are exposed in the cavity 40Y.

The surface-processed layer 80 is formed on the surfaces of the wiring layer 43A exposed in the cavity 40Y. The surface-processed layer 80 of the present embodiment includes a stack of the first metal layer 81 and the second metal layer 82.

The first metal layer 81 covers the entire upper surface and the entire side surface of the wiring layer 43A. The first metal layer 81 covers, for example, part of the side surface of the projection 42A of the insulating layer 42. The first metal layer 81 continuously covers the side surface of the projection 42A, the side surface of the wiring layer 43A, and the upper surface of the wiring layer 43A.

The second metal layer 82 covers the entire surface of the first metal layer 81. The second metal layer 82 covers the entire upper surface, the entire side surface, and the entire lower surface of the first metal layer 81. The second metal layer 82 continuously covers the upper surface, the side surface, and the lower surface of the first metal layer 81.

### Structure of Electronic Component 60

The electronic component 60 is flip-chip mounted on the wiring layer 43A exposed in the cavity 40Y. The first electrodes 62 of the electronic component 60 are electrically connected to the surface-processed layer 80, which is formed on the surfaces of the wiring layer 43A exposed in the cavity 40Y. The first electrodes 62 are electrically connected to the surface-processed layer 80 by the bonding members 64. In this manner, the electronic component 60 is electrically connected to the wiring layer 43A by the first electrodes 62, the bonding members 64, and the surface-processed layer 80.

### Structure of Underfill Resin 65

The underfill resin 65 is formed between the electronic component 60 and the bottom surface of the cavity 40X. The underfill resin 65 fills the gap between the lower surface of the main body 61 of the electronic component 60 and the bottom surface of the cavity 40Y. The underfill resin 65 encapsulates the first electrodes 62, the bonding members 64, and the surface-processed layer 80. The underfill resin 65 covers the entire side surface of the projection 42A exposed from the surface-processed layer 80.

### Wiring Structure 40

The insulating layer 49 is a filling insulating layer that fills the cavity 40Y. The insulating layer 49 covers the upper surface of the insulating layer 48, fills the cavity 40Y, and covers the electronic component 60. The insulating layer 49 covers, for example, the entire side surface of the underfill resin 65. The insulating layer 49 covers, for example, the entire bottom surface of the cavity 40Y exposed from the underfill resin 65. The insulating layer 49 covers, for example, the entire wall surface of the cavity 40Y exposed from the underfill resin 65. The insulating layer 49 covers, for example, the entire electronic component 60 exposed from the underfill resin 65.

### Method for Manufacturing Wiring Substrate 10A

A method for manufacturing the wiring substrate 10A will now be described. To facilitate understanding, portions that will consequently become elements of the wiring substrate 10A are given the same reference characters as the final elements.

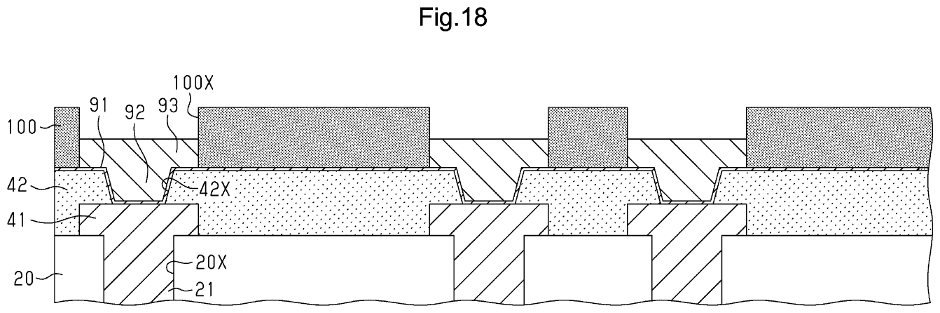

In the step illustrated in FIG. 18, steps similar to those illustrated in FIGS. 3 to 6 are performed to form the structural body illustrated in FIG. 18. In particular, the insulating layer 42 is first formed on the upper surface of the core substrate 20. The insulating layer 42 covers the wiring layer 41 and includes the through holes 42X. Then, the seed layer 91 is formed to continuously cover the upper surface of the insulating layer 42 and the wall surfaces of the through holes 42X. Subsequently, the resist layer 100, including the opening pattern 100X, is formed on the seed layer 91, and electrolytic plating is performed using the resist layer 100 as a plating mask. This step forms the metal layer 92 and the metal layer 93. The metal layer 92 fills the through holes 42X surrounded by the seed layer 91. The metal layer 93 is formed in the opening pattern 100X.

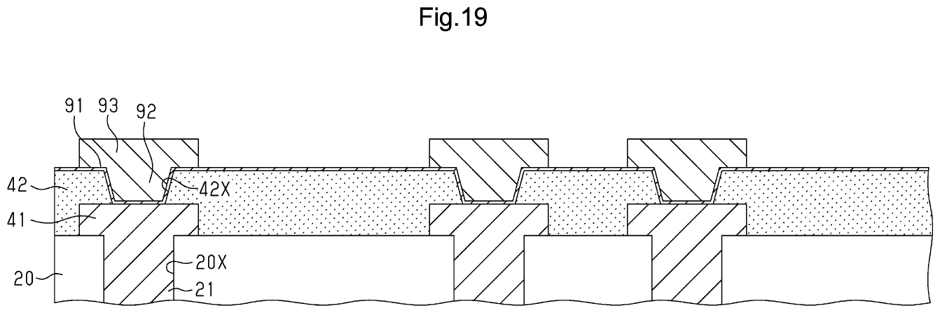

In the subsequent step illustrated in FIG. 19, the resist layer 100 illustrated in FIG. 18 is removed using an alkaline stripping solution (e.g., organic amine-based stripping solution, caustic soda, acetone, ethanol, or the like).

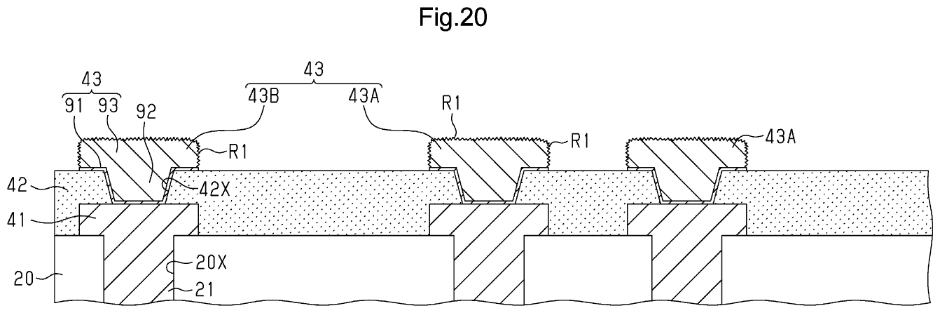

In the subsequent step illustrated in FIG. 20, unnecessary parts of the seed layer 91 are removed by etching using the metal layer 93 as an etching mask. This step forms via wiring and the wiring layer 43. The via wiring includes the seed layer 91 and the metal layer 92, which are formed inside the through holes 42X. The via wiring fills the through holes 42X. The wiring layer 43 includes the seed layer 91 and the metal layer 93. The wiring layer 43 is formed on the upper surface of the insulating layer 42. In this case, the wiring layer 43 includes the wiring layer 43A that overlaps the cavity 40Y in plan view (refer to FIG. 17), and the wiring layer 43B that does not overlap the cavity 40Y in plan view. The wiring layers 43A and 43B are formed in a later step. In FIGS. 17, the seed layer 91 and the metal layer 93 are not illustrated to simplify illustration.

Subsequently, a roughening process is performed on the wiring layers 43A and 43B. This roughening process forms the first roughened surface R1 on the entire upper surface and the entire side surface of the wiring layer 43A and the entire upper surface and the entire side surface of the wiring layer 43B. In particular, this step forms the first roughened surface R1 having a smaller surface roughness than the second roughened surface R2 illustrated in FIG. 17 on the upper surface of the wiring layer 43A. The roughening process may be performed by, for example, blackening, etching, blasting, or the like.

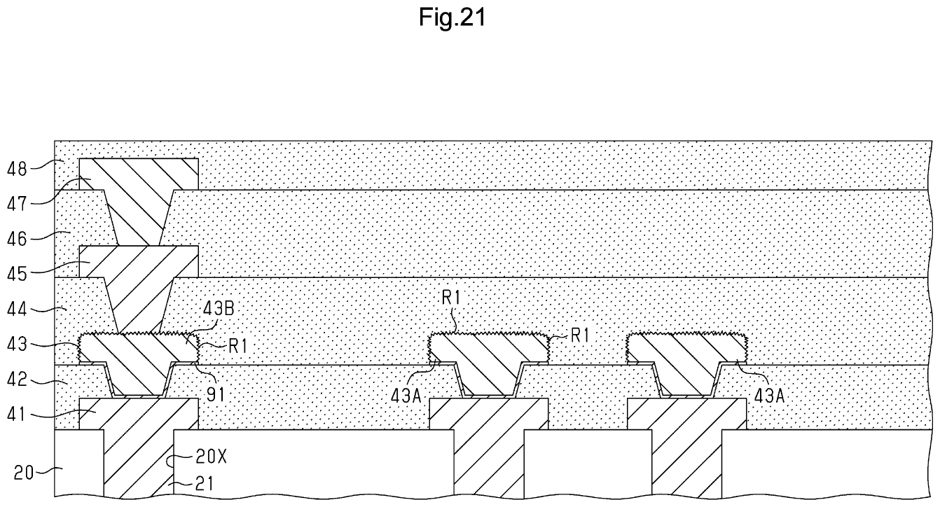

In the subsequent step illustrated in FIG. 21, steps similar to those illustrated in FIGS. 4 to 8 are performed to stack the insulating layer 44, the wiring layer 45, the insulating layer 46, the wiring layer 47, and the insulating layer 48 on the upper surface of the insulating layer 42. The insulation layer 48 covers the entire upper surface and the entire side surface of the wiring layer 47.

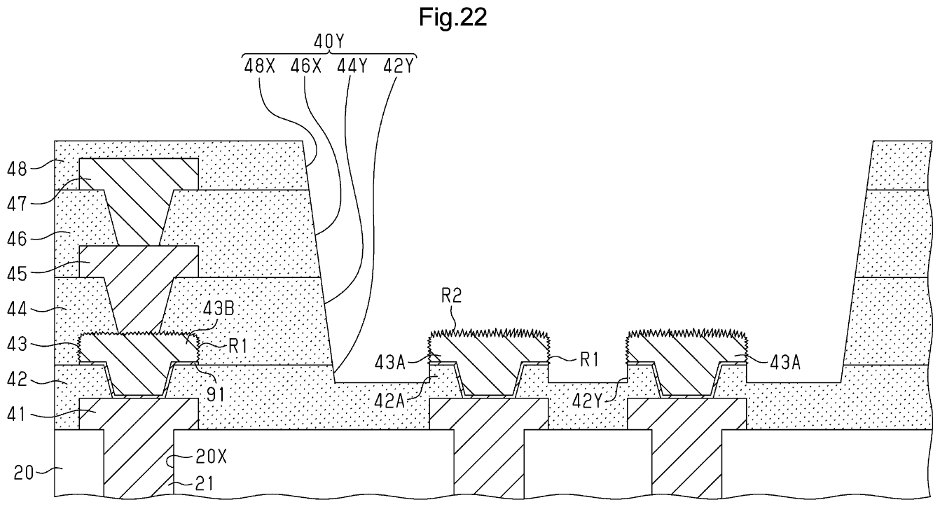

In the subsequent step illustrated in FIG. 22, the cavity 40Y is formed to expose the entire upper surface and the entire side surface of the wiring layer 43A. The cavity 40Y is recessed from the upper surface of the insulating layer 48 toward the core substrate 20. In the present example, the through hole 48X is formed to extend through the insulating layer 48, the through hole 46X is formed to be continuous with the through hole 48X and extends through the insulating layer 46, the through hole 44Y is formed to be continuous with the through hole 46X and extends through the insulating layer 44, and the recess 42Y is formed to be continuous with the through hole 44Y and recessed from the upper surface of the insulating layer 42. That is, the cavity 40Y extends through the insulating layers 48, 46, and 44 to an intermediate part of the insulating layer 42 in the thickness-wise direction. In other words, the cavity 40Y is recessed from the upper surface of the insulating layer 42 toward the core substrate 20. In this manner, even if the unnecessary parts of the seed layer 91 are not completely removed by the step illustrated in FIG. 20, the remainder of the seed layer 91 may be removed by laser drilling performed in the present step.

The cavity 40Y may be formed by, for example, laser drilling using CO₂ laser, UV-YAG laser, or the like. In the laser drilling, the upper surface of the wiring layer 43A is irradiated with a laser beam. This emission of the laser beam further roughens the upper surface of the wiring layer 43A. That is, the laser drilling increases the roughness of the upper surface of the wiring layer 43A. As a result, the upper surface of the wiring layer 43A includes the second roughened surface R2 having a greater surface roughness than the first roughened surface R1.

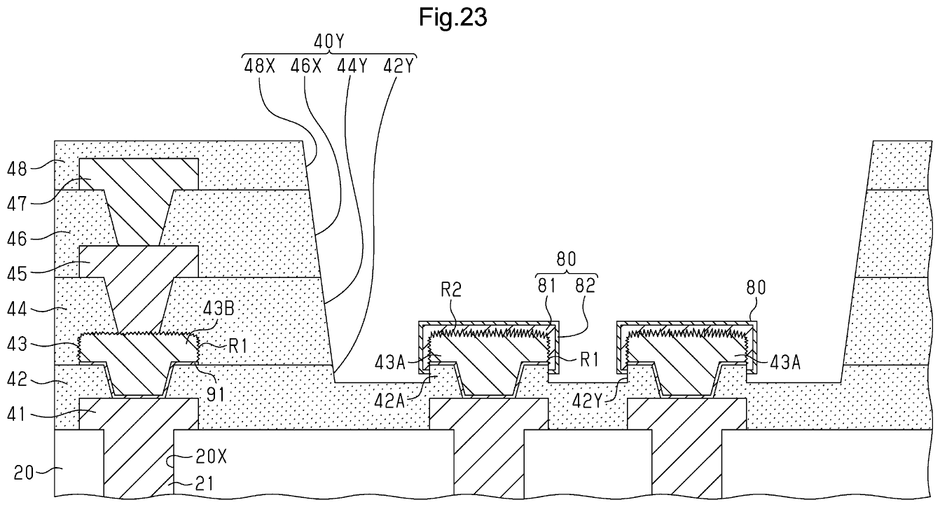

In the subsequent step illustrated in FIG. 23, the surface-processed layer 80 is formed on the surfaces of the wiring layer 43A exposed in the cavity 40Y. The surface-processed layer 80 covers the entire side surface and the entire upper surface of the wiring layer 43A. The surface-processed layer 80 may be formed by, for example, electroless plating. In an example, electroless plating (here, electroless Ni plating) is performed to form the first metal layer 81 (Ni layer) that covers the entire surface of the wiring layer 43A exposed in the cavity 40Y. The first metal layer 81 covers, for example, part of the side surface of the projection 42A of the insulating layer 42. Then, electroless plating (here, electroless Au plating) is performed to form the second metal layer 82 (Au layer) that covers the entire surface of the first metal layer 81, that is, the entire upper surface, the entire side surface, and the entire lower surface of the first metal layer 81. In the present step, the unnecessary parts of the seed layer 91 have been removed as described above, such that unintended deposition of a plating film caused by the remainder of the unnecessary parts of the seed layer 91 is restricted. This minimizes short-circuiting resulting from unintended deposition of a plating film.

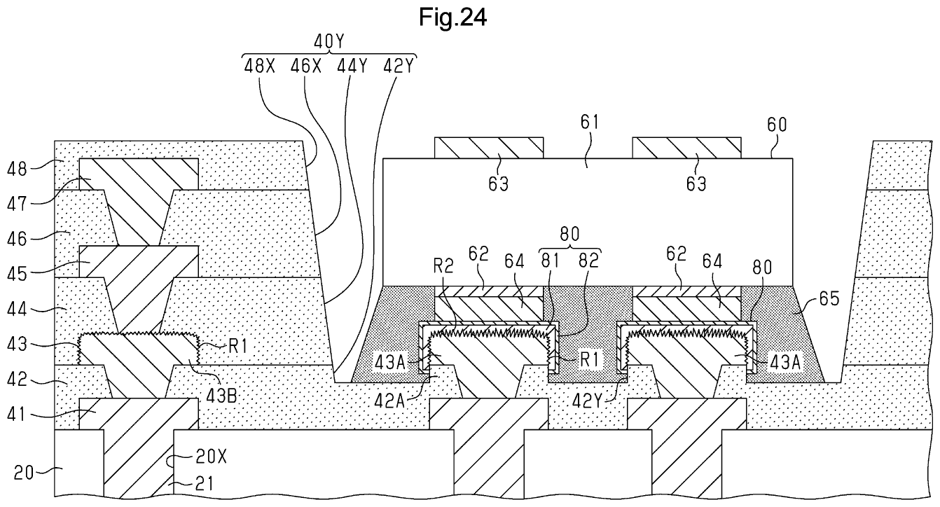

In FIGS. 24 to 27, the seed layer 91 and the metal layers 92 and 93 are not illustrated, and the wiring layer 43 is illustrated as a single layer.

In the subsequent step illustrated in FIG. 24, the electronic component 60 is prepared. The electronic component 60 includes the main body 61, the first electrodes 62, and the second electrodes 63. Then, the electronic component 60 is mounted on the surface-processed layer 80 in the cavity 40Y. Subsequently, the underfill resin 65 is added to fill the gap between the bottom surface of the cavity 40Y and the lower surface of the main body 61 of the electronic component 60, and then the underfill resin 65 is cured.

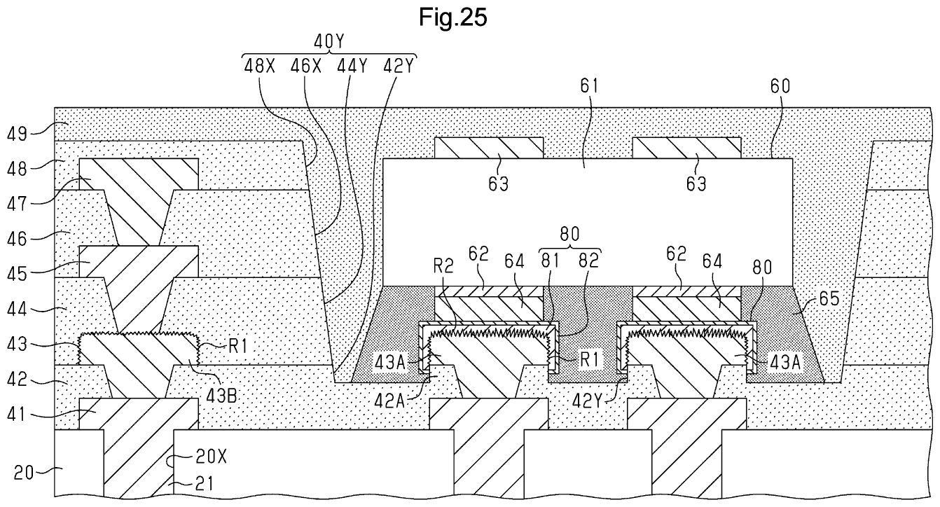

In the subsequent step illustrated in FIG. 25, a step similar to that illustrated in FIG. 4 is performed to form the insulating layer 49 that covers the upper surface of the insulating layer 48 and fills the cavity 40Y. The insulating layer 49 covers the entire side surface of the underfill resin 65 and the entire surface of the electronic component 60 exposed from the underfill resin 65.

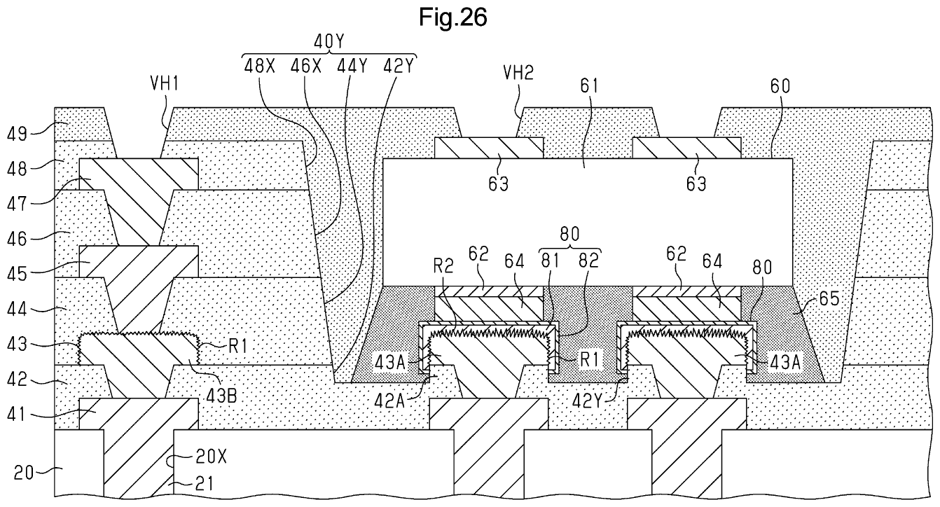

In the subsequent step illustrated in FIG. 26, a step similar to that illustrated in FIG. 4 is performed to form the through holes VH1 at given locations of the insulating layers 48 and 49. The through holes VH1 extend through the insulating layers 48 and 49 in the thickness-wise direction and expose parts of the upper surface of the wiring layer 47. Also, the through holes VH2 are formed at given locations of the insulating layer 49. The through holes VH2 extend through the insulating layer 49 in the thickness-wise direction and expose parts of the upper surface of the second electrode 63.

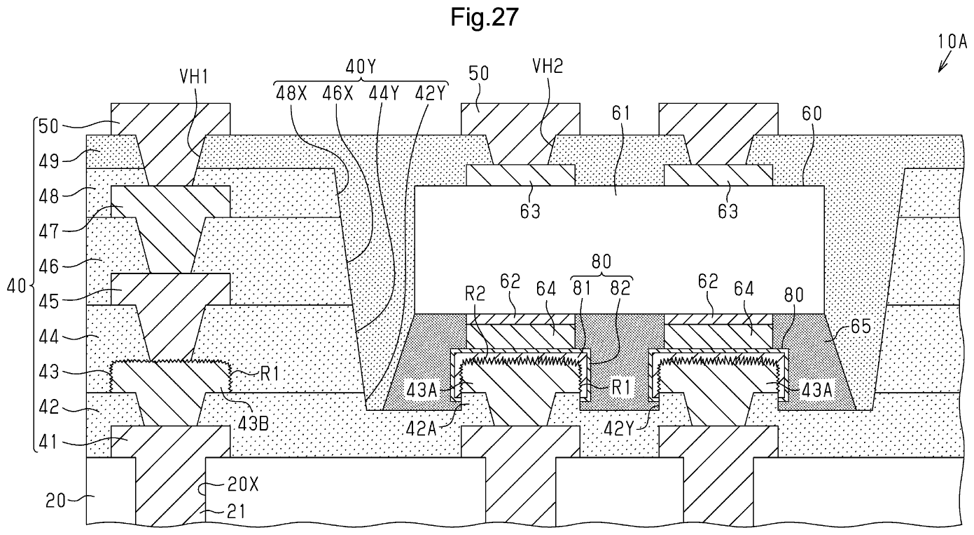

In the subsequent step illustrated in FIG. 27, steps similar to those illustrated in FIGS. 5 to 8 are performed to form via wiring filling the through holes VH1, and stack the wiring layer 50 on the upper surface of the insulating layer 49. In this manner, the wiring layer 50 is electrically connected to the wiring layer 47 by the via wiring. Also, via wiring is formed to fill the through holes VH2, and the wiring layer 50 is stacked on the upper surface of the insulating layer 49. In this manner, the wiring layer 50 is electrically connected to the second electrodes 63 by the via wiring.

The structural body illustrated in FIG. 17 may be manufactured as described above. Thereafter, the insulating layer 51, the wiring layer 52, and the like illustrated in FIG. 1 are formed to manufacture the wiring substrate 10A of the present embodiment.

### Operation and Advantages of Second Embodiment

In addition to the advantages (1-1) to (1-4) of the first embodiment, the second embodiment has the following advantages.
(2-1) The cavity 40Y is recessed from the upper surface of the uppermost insulating layer 48 of the “N” layers (here, “N” is three) of insulating layers, namely the insulating layers 44, 46, and 48, to an intermediate part of the insulating layer 42 in the thickness-wise direction. The cavity 40Y extends through the insulating layer 44 in the thickness-wise direction and exposes the entire side surface of the wiring layer 43A.

With this structure, even if the unnecessary parts of the seed layer 91 are not completely removed by the step illustrated in FIG. 20, the remainder of the seed layer 91 on the upper surface of the insulating layer 42 may be removed by laser drilling that is performed to form the cavity 40Y. Thus, when forming the surface-processed layer 80, unintended deposition of a plating film caused by the remainder of the unnecessary parts of the seed layer 91 is restricted. This minimizes short-circuiting resulting from unintended deposition of a plating film.
(2-2) The cavity 40Y includes the recess 42Y recessed from the upper surface of the insulating layer 42. The recess 42Y does not overlap the wiring layer 43A in plan view. With this structure, the recess 42Y is formed between two adjacent parts of the wiring layer 43A. This increases the creepage distance between the two adjacent parts of the wiring layer 43A, thereby restricting occurrence of short-circuiting caused by migration.

### Modified Examples

The above-described embodiments may be modified as described below. The above embodiments and the following modifications may be combined as long as the combined modifications remain technically consistent with each other.

The structures of the wiring substrates 10 and 10A in the above embodiments may be modified.

For example, the number of wiring layers, the wiring layout, or the number of insulating layers of the wiring structure 30 may be modified in various manners.

In the above embodiments, the solder resist layer 70 may be omitted.

In the above embodiments, the wiring structure 30 may be omitted.

For example, the number of wiring layers, the wiring layout, or the number of insulating layers of the wiring structure 40 may be modified in various manners.

In the wiring structure 40 of the first embodiment, the three insulating layers 44, 46, and 48 serve as the cavity formation insulating layers. Instead, a cavity may be formed through a single insulating layer, two insulating layers, or four or more insulating layers.

In the wiring structure 40 of the second embodiment, the four insulating layers 42, 44, 46, and 48 serve as the cavity formation insulating layers. Instead, a cavity may be formed through a single insulating layer, two insulating layers, three insulating layers, or five or more insulating layers.

In the wiring structure 40 of the above embodiments, a metal pattern may be formed along the perimeter of the bottom of the cavity 40X, 40Y. In this case, a metal pattern is exposed along the perimeter of the bottom of the cavity 40X, 40Y.

In the wiring substrates 10 and 10A of the above embodiments, there is no limit to the number of wiring layers or insulating layers stacked on the upper surface of the insulating layer 49 filling the cavity.

The wiring substrates 10 and 10A of the above embodiments are embodied in a build-up wiring substrate including the core substrate 20. However, there is no limitation to such a structure. For example, the wiring substrates 10 and 10A may be embodied in a coreless wiring substrate that does not include the core substrate 20.

There is no limit to the number of electronic components 60 incorporated in the wiring substrates 10 and 10A of the above embodiments. For example, a plurality of electronic components 60 may be incorporated in the wiring substrates 10 and 10A. In this case, the number of cavities 40X, 40Y may be the same as the number of incorporated electronic components 60. Alternatively, the multiple electronic components 60 may be arranged in a single cavity 40X, 40Y.

In the above embodiments, the wiring substrate 10, 10A incorporates the electronic component 60 having two types of electrodes, namely, the first electrode 62 and the second electrode 63. However, there is no limitation to such a structure. For example, an electronic component having three or more types of electrodes may be incorporated in the wiring substrate 10, 10A.

In the above embodiments, the structure of the electronic component 60 may be changed. For example, the second electrodes 63 may be omitted. In this case, the electronic component 60 only includes the first electrodes 62 on the lower surface of the main body 61.

In the above embodiments, the present disclosure is embedded in a method for manufacturing a single unit (one unit) of a substrate. Instead, the present disclosure may be embedded in a method for manufacturing a batch of substrates.

### CLAUSES

This disclosure further encompasses the following embodiments.

1. A method for manufacturing a wiring substrate, the method including:
forming a first wiring layer;
forming a first insulating layer covering the first wiring layer;
forming a second wiring layer on an upper surface of the first insulating layer, the second wiring layer being electrically connected to the first wiring layer;
forming, by a roughening process, a first roughened surface on an upper surface of the second wiring layer and a side surface of the second wiring layer;
forming “N” layers of insulating layers including a second insulating layer, the second insulating layer being stacked on the upper surface of the first insulating layer and covering the second wiring layer, wherein “N” is a natural number greater than or equal to 1;
forming, by laser drilling, a cavity through the “N” layers of insulating layers, the cavity exposing the upper surface of the second wiring layer and the side surface of the second wiring layer;
roughening, by the laser drilling, the upper surface of the second wiring layer;
forming a surface-processed layer covering the upper surface of the second wiring layer and the side surface of the second wiring layer that are exposed in the cavity;
mounting an electronic component on the surface-processed layer in the cavity;
forming a filling insulating layer that fills the cavity and covers the electronic component; and
forming a third wiring layer on an upper surface of the filling insulating layer, the third wiring layer being electrically connected to the electronic component,
in which the upper surface of the second wiring layer roughened by the laser drilling includes a second roughened surface having a surface roughness that is greater than the first roughened surface.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A wiring substrate, comprising:
a first wiring layer;
a first insulating layer covering the first wiring layer;
a second wiring layer stacked on an upper surface of the first insulating layer and electrically connected to the first wiring layer;
“N” layers of insulating layers including a second insulating layer stacked on the upper surface of the first insulating layer, wherein “N” is a natural number greater than or equal to 1;
a cavity formed through the “N” layers of insulating layers and exposing an upper surface of the second wiring layer and a side surface of the second wiring layer;
a surface-processed layer covering the upper surface of the second wiring layer and the side surface of the second wiring layer that are exposed in the cavity;
an electronic component arranged in the cavity and mounted on the surface-processed layer;
a filling insulating layer filling the cavity and covering the electronic component; and
a third wiring layer stacked on an upper surface of the filling insulating layer and electrically connected to the electronic component, wherein
the side surface of the second wiring layer includes a first roughened surface, and
the upper surface of the second wiring layer includes a second roughened surface having a surface roughness that is greater than the first roughened surface.

2. The wiring substrate according to claim 1, further comprising:
a fourth wiring layer stacked on the upper surface of the first insulating layer and electrically connected to the first wiring layer, wherein
the fourth wiring layer does not overlap the cavity in plan view, and
a side surface of the fourth wiring layer and an upper surface of the fourth wiring layer each include the first roughened surface.

3. The wiring substrate according to claim 1, wherein
the cavity is recessed from an upper surface of an uppermost insulating layer of the “N” layers of insulating layers to an intermediate part of the second insulating layer in a thickness-wise direction,
the cavity exposes part of the side surface of the second wiring layer, and
the surface-processed layer covers an entirety of the upper surface of the second wiring layer and an entirety of the side surface of the second wiring layer exposed in the cavity.

4. The wiring substrate according to claim 3, wherein
the second wiring layer includes a seed layer formed on the upper surface of the first insulating layer, and a metal layer formed on an upper surface of the seed layer, and
a bottom surface of the cavity is located upward from the upper surface of the seed layer.

5. The wiring substrate according to claim 1, wherein
the cavity is recessed from an upper surface of an uppermost insulating layer of the “N” layers of insulating layers to an intermediate part of the first insulating layer in a thickness-wise direction,
the cavity extends through the second insulating layer in the thickness-wise direction and exposes an entirety of the side surface of the second wiring layer, and
the surface-processed layer covers an entirety of the upper surface of the second wiring layer and the entirety of the side surface of the second wiring layer.

6. The wiring substrate according to claim 5, wherein
the cavity includes a recess recessed from the upper surface of the first insulating layer, and
the recess does not overlap the second wiring layer in plan view.

7. The wiring substrate according to claim 6, wherein
the first insulating layer includes a projection projecting upward from a bottom surface of the recess and overlapping the second wiring layer in plan view, and
the surface-processed layer covers the entirety of the upper surface of the second wiring layer, the entirety of the side surface of the second wiring layer, and a side surface of the projection.

8. The wiring substrate according to claim 2, further comprising:
the second insulating layer stacked on the upper surface of the first insulating layer and covering the fourth wiring layer;
a fifth wiring layer stacked on an upper surface of the second insulating layer and electrically connected to the fourth wiring layer;
a third insulating layer stacked on the upper surface of the second insulating layer and covering the fifth wiring layer;
a sixth wiring layer stacked on an upper surface of the third insulating layer and electrically connected to the fifth wiring layer; and
a fourth insulating layer stacked on the upper surface of the third insulating layer and covering the sixth wiring layer,
wherein the “N” layers of insulating layers include the second insulating layer, the third insulating layer, and the fourth insulating layer.

9. The wiring substrate according to claim 1, wherein
the electronic component includes a main body, a first electrode arranged on a lower surface of the main body, and a second electrode arranged on an upper surface of the main body,
the first electrode is electrically connected to the surface-processed layer by a bonding member, and
the third wiring layer is electrically connected to the second electrode.

10. The wiring substrate according to claim 8, further comprising:
an underfill resin filling a gap between a bottom surface of the cavity and the electronic component,
wherein the filling insulating layer covers an entirety of a side surface of the underfill resin.

11. The wiring substrate according to claim 1, wherein
the cavity includes a bottom surface and an upper open end, and
the cavity is tapered to have an opening width that decreases from the upper open end toward the bottom surface.

12. The wiring substrate according to claim 1, wherein
the electronic component includes a main body, a first electrode arranged on a lower surface of the main body, and a second electrode arranged on an upper surface of the main body, and
the third wiring layer is electrically connected to the second electrode.

13. The wiring substrate according to claim 12, wherein the second wiring layer is electrically connected to the first electrode of the electronic component.
